(19) United States
(12) Patent Application Publication
(10) Pub. No.: US 2008/0017902 A1
(43) Pub. Date: Jan. 24, 2008

(54) SEMICONDUCTOR DEVICE AND METHOD OF MANUFACTURING THE SAME

(75) Inventor: Wensheng WANG, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 11/862,606

(22) Filed: Sep. 27, 2007

Related U.S. Application Data
(63) Continuation of application No. PCT/JP2005/006183, filed on Mar. 30, 2005.

(51) Int. Cl. H01L 29/94

(52) U.S. Cl. 257/295

(57) ABSTRACT

A semiconductor device comprises an inter-layer insulation film 30 formed on a semiconductor substrate 10, and a dielectric capacitor including a lower electrode 38 formed on the inter-layer insulation film 30 including a conduction film 36 of a noble metal or noble metal oxide, a dielectric film 42 formed on the lower electrode 38, and an upper electrode 44 formed on the dielectric film 42, the lower electrode 38 being integrated with a plug portion 38a buried in a contact hole 32a formed in the inter-layer insulation film 30 and connected to a source/drain region 22a.

### CROSS REFERENCE TO RELATED APPLICATIONS

This application is a Continuation of International Application No. PCT/JP2005/006183, with an international filing date of Mar. 30, 2005, which designating the United States of America, the entire contents of which are incorporated herein by reference.

### TECHNICAL FIELD

The present invention relates to a semiconductor device and a method of manufacturing the same, more specifically, a semiconductor device including a capacitor using a high dielectric film or a ferroelectric film as the dielectric film and a method of manufacturing the same.

### BACKGROUND

In the background that with the progress of the recent digital technique, high-speed storage, processing, etc. of large volumes of data are increasingly required, semiconductor devices used in electronic apparatuses are required to be highly integrated and highly operative. In order to meet such requirements, as for DRAM (Dynamic Random Access Memory), for example, techniques of using ferroelectric materials and high dielectric materials as the dielectric film forming the capacitors of DRAM have been widely studied and developed so as to realize the high integration of DRAM.

FeRAM (Ferroelectric Random Access Memory), which comprises ferroelectric capacitors including the dielectric film of ferroelectric film, is a nonvolatile memory characterized by high-speed operation, low electric power consumption, good write/read endurance, etc. and is considered prospective.

FeRAM is a memory which utilizes the hysteresis characteristics of ferroelectrics to store information. In a ferroelectric capacitor including a ferroelectric film sandwiched by a pair of electrodes, the ferroelectric film is polarized corresponding to an applied voltage between the electrodes and has spontaneous polarization after the voltage application between the electrodes is stopped. When a polarity of the applied voltage between the electrodes is inversed, the polarity of the spontaneous polarization is also inversed. Thus, information corresponding to the polarity of the spontaneous polarization of the ferroelectric film is stored, and the spontaneous polarization is detected to read the stored information.

The materials of the ferroelectric film used in the ferroelectric capacitors of FeRAM are PZT-based ferroelectrics, such as PbZr_{1-X}Ti_{X}O₃ (PZT), Pb_{1-X}La_{X}Zr_{1-Y}Ti_{Y}O₃ (PLZT), PZT doped with a trace of Ca, Sr or Si, etc. Ferroelectrics of bismuth layered structure, such as SrBi₂Ta₂O₉ (SBT), SrBi₂(Ta_{X}Nb_{1-X})O₉ (SBTN), etc., or others are used. Such ferroelectric film is formed by sol-gel process, sputtering, MOCVD (Metal Organic Chemical Vapor Deposition) or others.

Generally, the ferroelectric film used in the ferroelectric capacitor is formed on the lower electrode by sol-gel process mentioned above and is crystallized by thermal processing into crystals of perovskite structure or of bismuth layered structure. Accordingly, it is essential that the electrode material of the ferroelectric capacitor is hard to oxidize or maintains the conductivity even oxidized. As such electrode materials, metals of the platinum group or oxides of the platinum group metals such as Pt, Ir, IrO_{X}, etc. are widely used. The other interconnection materials of FeRAM are generally Al, etc. which are used in the ordinary semiconductor devices.

For FeRAM as well other semiconductor devices, it is a future problem to reduce the cell area. As a structure which can realize the reduction of the cell area of FeRAM, the stack type cell is noted.

In the stack type cell, a ferroelectric capacitor is formed directly above a plug connected to a source/drain region of a transistor formed on a semiconductor substrate. That is, on the plug connected to the source/drain region, a barrier metal, a lower electrode, a ferroelectric film and an upper electrode are sequentially formed. The plug is formed of tungsten. The barrier metal plays the role of suppressing the diffusion of oxygen. Generally, a conduction film functioning as the lower electrode and the barrier metal is formed. Accordingly, it is difficult to discriminate the barrier metal and the lower electrode clearly from each other, but as materials of such conduction film, combinations of TiN, TiAlN, Ir, Ru, IrO₂, RuO₂, SrRuO₃ (SRO) are being studied.

As described above, as the electrode material of the ferroelectric capacitor, the platinum group metals or oxides of the platinum group metals are used. However, Pt has high permeability to oxygen. Accordingly, in the stack type cell, with Pt film formed as the lower electrode directly below the tungsten plugs, oxygen easily permeates the Pt film, and the tungsten plug is often easily oxidized by thermal processing. In order to suppress such oxidation of the tungsten plugs, the stack type cell has come to more use as the structure of the lower electrode the structure of an Ir film and a Pt film sequentially laid (Pt/Ir structure) and the structure of an Ir film, an IrO₂ film and a Pt film sequentially laid (Pt/IrO₂/Ir structure). Furthermore, various layered structures of the lower electrode are proposed (refer to, e.g., Japanese Patent Application No. 2003-425784, Specification of Japanese Patent No. 3454085 and Japanese Published Unexamined Patent Application No. Hei 11-243179). Techniques of forming various barrier metals on the inside walls of the contact holes with the tungsten plugs buried in to thereby realize the prevention of the resistance increase of the connection between the tungsten plug and the lower electrode, the characteristics deterioration of the ferroelectric capacitor, etc. (refer to, e.g., Japanese Published Unexamined Patent Application No. 2004-31533 and Japanese Published Unexamined Patent Application No. 2003-68993).

Generally, circuits connected to the ferroelectric capacitors are formed of Al interconnections. It is known that Al causes eutectic reaction with the platinum group metals, such as Pt, etc. (refer to, e.g., Japanese Published Unexamined Patent Application No. 2004-241679). To prevent the eutectic reaction between both, a barrier layer of TiN film or others must be formed between the electrode of the platinum group metal and the Al interconnections (refer to, e.g., Specification of Japanese Patent No. 3045928 and Specification of Japanese Patent No. 3165093).

However, the use of TiN film and the layered film of Ti film and TiN film used in the usual logic devices, etc. cannot prevent the reaction between the electrode material and interconnection material, the oxidation of the Ti film, etc., resultantly often causing inconveniences, such as defective contacts, etc. To prevent such inconveniences, various structure, material, etc. of the barrier layer are proposed (see, e.g., Japanese Published Unexamined Patent Application No. 2002-100740 and Specification of Japanese Patent No. 3307609).

In the stack type cell of FeRAM, the tungsten plug is generally used. Various structures of the barrier layer, etc. formed between the lower electrode of the ferroelectric capacitor and the tungsten plug for the prevention of oxidation of the tungsten plug are proposed (refer to, e.g., Japanese Published Unexamined Patent Application No. 2004-193430 and Japanese Published Unexamined Patent Application No. 2004-146772).

In the conventional FeRAM, tungsten plugs, which are liable to be oxidized, are used, and the tungsten plugs are often oxidized by thermal processing, etc. during the manufacturing process. Once a tungsten plug is oxidized, the film release and the defective contact of the lower electrode, etc. on the tungsten plug often take place. Japanese Published Unexamined Patent Application No. 2004-193430 and Japanese Published Unexamined Patent Application No. 2004-146772 disclose structures for preventing the oxidation of the tungsten plugs, but the structures are complicated. Even use of such structures will be difficult to prevent without failure the oxidation of the tungsten plugs in the thermal processing for the crystallization of the ferroelectric film, the recovery from damages, etc.

For the prevention of the eutectic reaction of Pt, etc. as the electrode material of the ferroelectric capacitor and Al as the interconnection material, a barrier layer of a Ti film, a TiN film or others is formed, but often such barrier layer cannot prevent the eutectic reaction. For example, when stresses of the wafer are changed by the thermal processing after the formation of the barrier layer, cracks are formed in the barrier layer often with a result that the eutectic reaction takes place between the Pt, etc. as the electrode material and the Al as the interconnection material.

The tungsten plug is not well planarized by the polish of CMP (Chemical Mechanical Polishing), which often degrades the orientation of the lower electrode formed on the tungsten plug. Resultantly, the crystallinity of the ferroelectric film formed on the lower electrode is also deteriorated, which often degrades the electric characteristics of the ferroelectric capacitor.

### SUMMARY

The present invention is directed to various embodiments of a semiconductor device and a method for manufacturing the semiconductor device having a plug connected to the lower electrode, a plug including a conduction film of a noble metal or a noble metal oxide.

### BRIEF DESCRIPTION OF DRAWINGS

FIG. 1 is a sectional view showing the structure of the semiconductor device according to a first embodiment of the present invention.

FIGS. 2A to 2J are sectional views showing the method of manufacturing the semiconductor device according to the first embodiment of the present invention.

FIG. 3 is a sectional view showing the structure of the semiconductor device according to a modification of the first embodiment of the present invention.

FIG. 4 is a sectional view showing the structure of the semiconductor device according to a second embodiment of the present invention.

FIGS. 5A to 5F are sectional views showing the method of manufacturing the semiconductor device according to the second embodiment of the present invention.

FIG. 6 is a sectional view showing the structure of the semiconductor device according to a modification of the second embodiment of the present invention.

FIG. 7 is a sectional view showing the structure of the semiconductor device according to a third embodiment of the present invention.

FIGS. 8A to 8F are sectional views showing the method of manufacturing the semiconductor device according to the third embodiment of the present invention.

FIG. 9 is a sectional view showing the structure of the semiconductor device according to a fourth embodiment of the present invention.

FIGS. 10A to 10L are sectional views showing the method of manufacturing the semiconductor device according to the fourth embodiment of the present invention.

### DETAILED DESCRIPTION OF THE EMBODIMENTS

### A First Embodiment

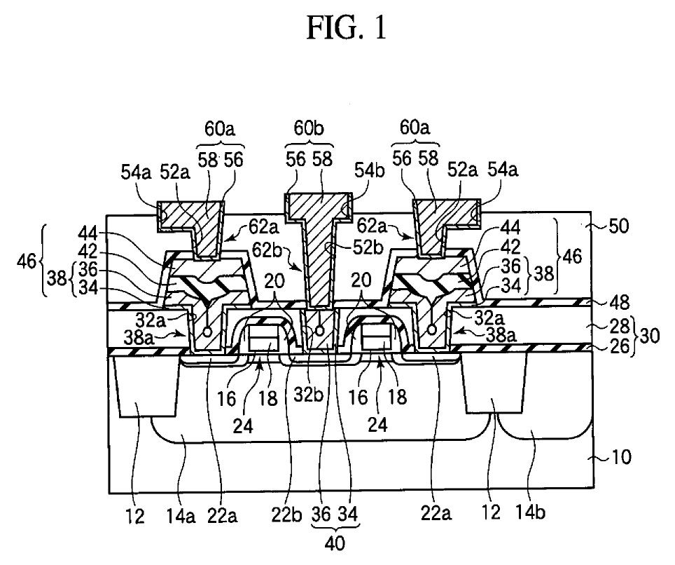

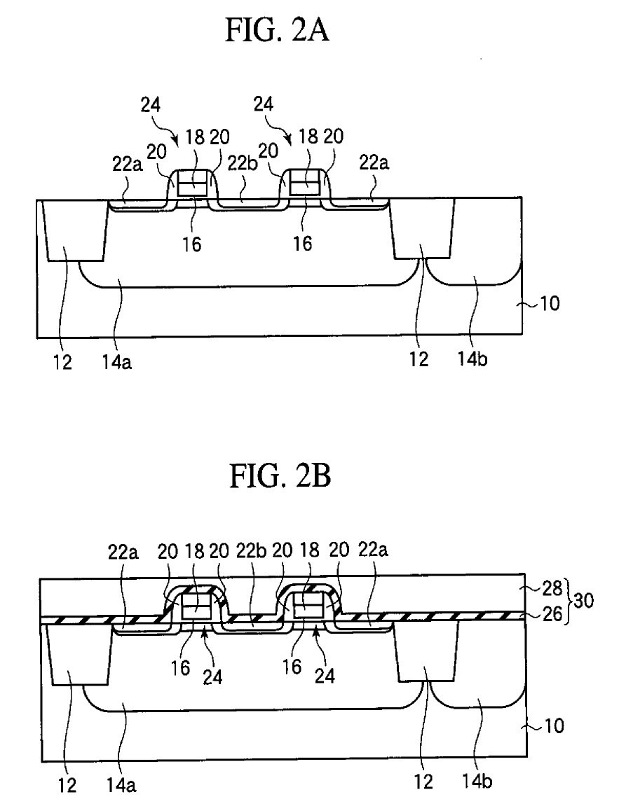

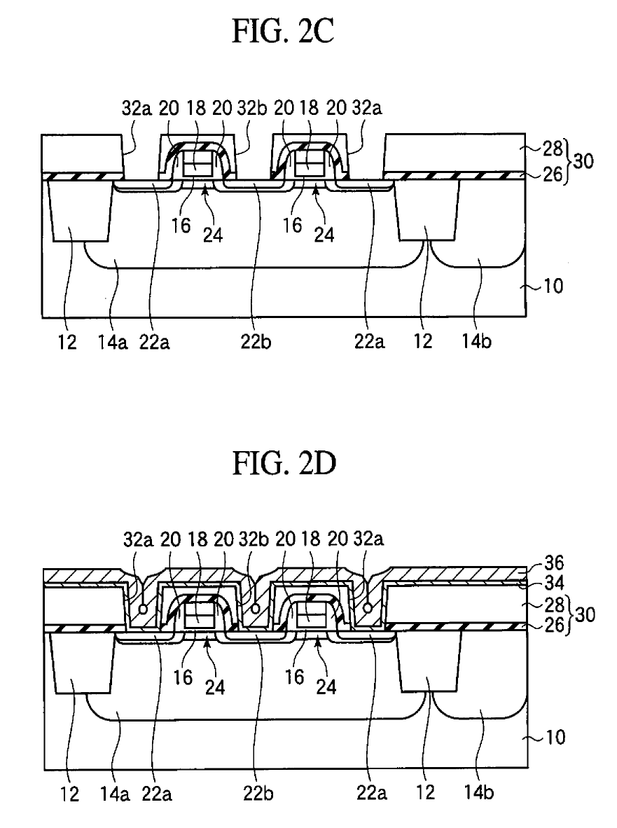

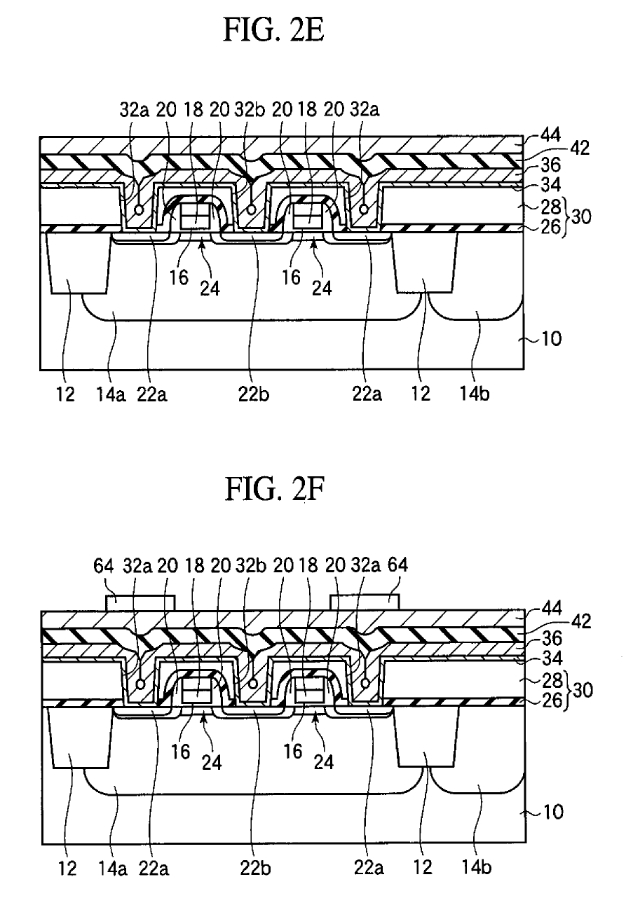

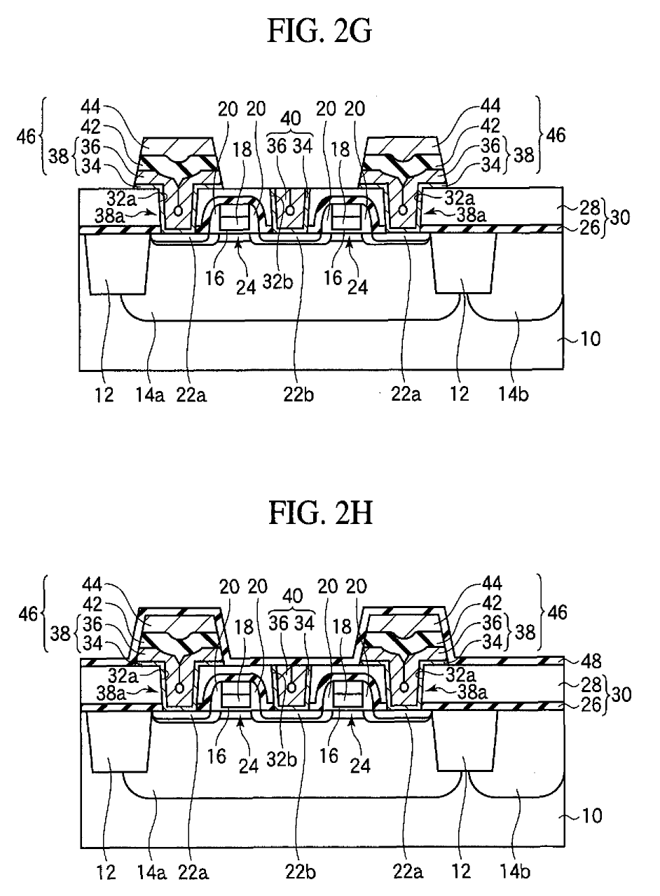

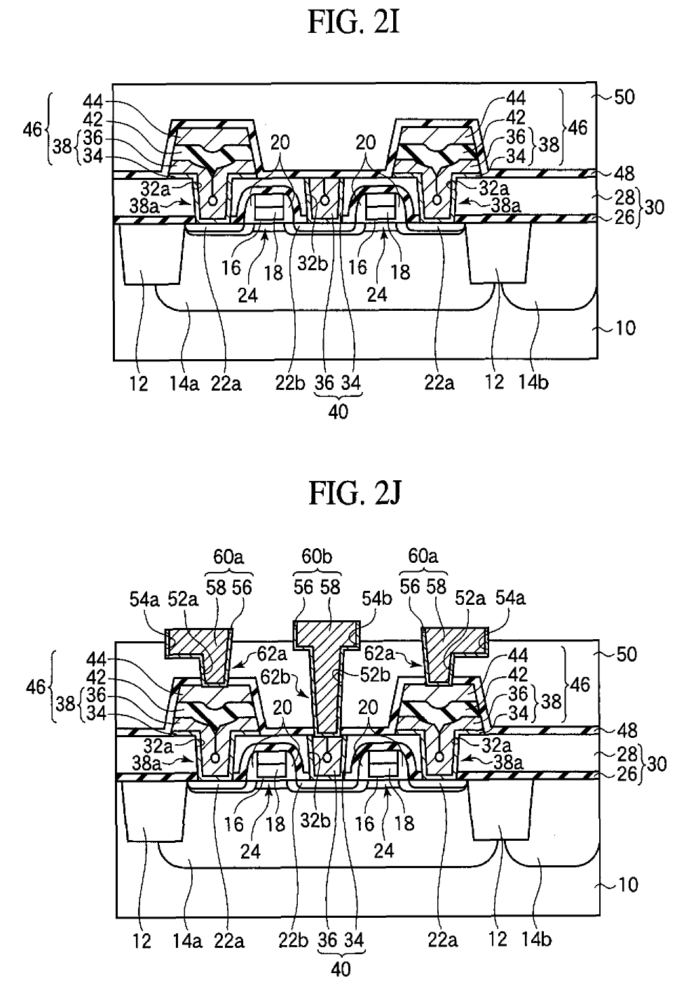

The semiconductor device and the method of manufacturing the same according to a first embodiment of the present invention will be explained with reference to FIGS. 1 to 2J. FIG. 1 is a sectional view showing the structure of the semiconductor device according to the present embodiment. FIGS. 2A to 2J are sectional views showing the method of manufacturing the semiconductor device according to the present embodiment.

First, the structure of the semiconductor device according to the present embodiment will be explained with reference to FIG. 1. The semiconductor device according to the present embodiment is an FeRAM of the stack type memory cell structure.

A device isolation region 12 for defining a device region is formed on a semiconductor substrate 10 of, e.g., silicon. The semiconductor substrate 10 can be either of n-type and p-type. In the semiconductor substrate 10 with the device isolation region 12 formed on, wells 14a, 14b are formed.

On the semiconductor substrate 10 with the wells 14a, 14b formed in, gate electrodes (gate lines) 18 are formed with a gate insulation film 16 formed therebetween. A sidewall insulation film 20 is formed on the side wall of the gate electrode 18.

Source/drain regions 22a, 22b are formed on both sides of the gate electrode 18 with the sidewall insulation film 20 formed on.

Thus, transistors 24 each including the gate electrode 18 and the source/drain regions 22a, 22b are formed on the semiconductor substrate 10.

On the semiconductor substrate 10 with the transistors 24 formed on, a 200 nm-thickness silicon oxynitride film (SiON film) 26, for example, and a 1000 nm-thickness silicon oxide film 28, for example, are sequentially laid. Thus, an inter-layer insulation film 30 of the SiON film 26 and the silicon oxide film 28 sequentially laid is formed. The surface of the inter-layer insulation film 30 is planarized.

In the inter-layer insulation film 30, contact holes 32a, 32b are formed down to the source/drain regions 22a, 22b.

On the inside wall of the contact hole 32a, on the source/drain region 22a at the bottom of the contact hole 32a and on the inter-layer insulation film 30 around the contact hole 32a, an adhesion layer 34 for ensuring the adhesion of a conduction film 36 of noble metal which will be described later to the base is formed. On the inside wall of the contact hole 32b and the source/drain region 22b at the bottom of the contact hole 32b, the adhesion layer 34 for ensuring the adhesion of the noble metal conduction film 36 of which will be described later to the base is formed. The adhesion layer 34 is formed of, e.g., a 20 nm-thickness Ti film and, e.g., a 50 nm-thickness TiN film sequentially laid. The adhesion layer 43 also functions as the barrier layer for preventing the diffusion of hydrogen and water. Such adhesion layer 34 prohibits the arrival of hydrogen and water at a ferroelectric film 42 to thereby suppress the reduction of the metal oxide forming the ferroelectric film 42 with hydrogen and water. Thus, the deterioration of the electric characteristics of a ferroelectric capacitor 46 can be suppressed.

The conduction film 36 of noble metal is formed in the contact hole 32a with the adhesion layer 34 formed in and on the adhesion layer 34 around the contact hole 32a. In the contact hole 32b with the adhesion layer 34 formed in, the conduction film 36 is buried. The conduction film 36 is, e.g., a 400 nm-thickness iridium (Ir) film.

Thus, the lower electrode 38 of the ferroelectric capacitor 46 is formed of the adhesion layer 34 and the noble metal conduction film 36. The lower electrode 38 is buried in the contact hole 32a and has an integrated plug portion 38a connected to the source/drain region 22a.

In the contact hole 32b, a plug 40 formed of the adhesion layer 34 and the noble metal conduction film 36 and connected to the source/drain region 22b is formed.

On the lower electrode 38, a ferroelectric film 42 of the ferroelectric capacitor 46 is formed. The ferroelectric film 42 is, e.g., a 120 nm-thickness PbZr_{1-X}Ti_{X}O₃ film (PZT film).

On the ferroelectric film 42, the upper electrode 44 of the ferroelectric capacitor 46 is formed. The upper electrode 44 is formed of, e.g., a 200 nm-thickness iridium oxide (IrO₂) film.

Thus, the ferroelectric capacitors 46 each including the lower electrode 38, the ferroelectric film 42 and the upper electrode 44 are constituted.

On the inter-layer insulation film 30 with the ferroelectric capacitors 46 formed on, a protection film 48 for preventing the diffusion of hydrogen and water is formed. The protection film 48 is formed, covering the ferroelectric capacitors 46, i.e., covering the side surfaces of the lower electrodes 38, the side surfaces of the ferroelectric films 42, the side surfaces of the upper electrodes 44 and the upper surfaces of the upper electrodes 44. The protection film 48 is, e.g., a 20-100 nm-thickness an alumina (Al₂O₃) film. The protection film 48 prevents the arrival of hydrogen and water at the ferroelectric film 42 to thereby suppress the reduction of the metal oxide forming the ferroelectric film 42 with hydrogen and water. Thus, the deterioration of the electric characteristics of the ferroelectric capacitor 46 can be suppressed.

On the protection film 48, an inter-layer insulation film 50 of, e.g., a 1500 nm-thickness TEOS film is formed. The surface of the inter-layer insulation film 50 is planarized.

Contact holes 52a are formed in the inter-layer insulation film 50 and the protection film 48 down to the upper electrodes 44 of the ferroelectric capacitors 46. Interconnection trenches 54a connected to the contact holes 52a are formed in the inter-layer insulation film 50.

In the inter-layer insulation film 50 and the protection film 48, a contact hole 52b is formed down to the plug 40. An interconnection trench 54b connected to the contact hole 52b is formed in the inter-layer insulation film 50.

In the contact hole 52a and the interconnection trench 54a and in the contact hole 52b and the interconnection trench 54b, a barrier metal film 56 of, e.g., a 30 nm-thickness Ti film and a 50 nm-thickness TiN film is formed.

An Aluminum film 58 is buried in the contact hole 52a and the interconnection trench 54a with the barrier metal film 56 formed in and in the contact hole 52b and the interconnection trench 54b with the barrier metal 56 formed in. The aluminum film 58 may be tungsten film.

Thus, in the interconnection trenches 54a, interconnections 60a of the barrier metal film 56 and the aluminum film 58 are formed. The interconnection 60a is integrated with a plug portion 62a buried in the contact hole 52a and connected to the upper electrode 44 of the ferroelectric capacitor 46.

In the interconnection trench 54b, an interconnection 60b formed of the barrier metal film 56 and the aluminum film 58 is formed. The interconnection 60b is integrated with a plug portion 62b buried in the contact hole 52b and connected to the plug 40.

Thus, the semiconductor device according to the present embodiment is constituted.

The semiconductor device according to the present embodiment is characterized mainly in that the lower electrode 38 of the ferroelectric capacitor 46 has noble metal conduction film 36 and is integrated with the plug portion 38a connected to the source/drain region 22a.

Conventionally in the stack type memory cell structure, a lower electrode of a ferroelectric capacitor is formed separately and directly on a tungsten plug connected to a source/drain region. The tungsten plug does not have good planarity after CMP, which degrades the orientation of the lower electrode. The tungsten plug is easily oxidized by thermal processing made on the ferroelectric capacitor. When the tungsten plug is oxidized, the adhesion between the tungsten plug and the lower electrode is lowered, and the film is released, with the result of the defective contact between the tungsten plug and the lower electrode.

As compared with the conventional structure, in the semiconductor device according to the present embodiment, the lower electrode 38 of the ferroelectric capacitor 46 has the noble metal conduction film 36 which is hard to be oxidized, and is integrated with the plug portion 38a connected to the source/drain region 22a. Thus, the lower electrode 38 of a required orientation can be formed with high control in comparison with the case that the tungsten plug, which are liable to be oxidized, are formed separate from the lower electrode. Accordingly, the crystallinity of the ferroelectric film 42 to be formed on the lower electrode 38 can be improved, and the ferroelectric capacitor 46 can have good electric characteristics.

The semiconductor device according to the present embodiment includes the lower electrode 38 integrated with the plug portion 38a connected to the source/drain region 22a, and is free from the problem of the defective contact between the tungsten plug and the lower electrode of the conventional case, in which they are formed separate.

The conduction film 36 forming the lower electrode 38 having the plug portion 38a is formed on a noble metal which is hard to be oxidized and remains low resistive even when oxidized, whereby good contact can be realized.

The oxide of a noble metal forming the conduction film 36 has the property of preventing the diffusion of hydrogen and water. Accordingly, as far as the conduction film 36 of a noble metal is oxidized, the arrival of hydrogen and water at the ferroelectric film 42 can be prevented, and the reduction of the metal oxide forming the ferroelectric film 42 with hydrogen and water can be suppressed. Thus, the deterioration of the electric characteristics of the ferroelectric capacitor 46 can be suppressed.

Thus, according to the present embodiment, an FeRAM of the stack type memory cell structure having good operational characteristics and high reliability can be provided.

Next, the method of manufacturing the semiconductor device according to the present embodiment will be explained with reference to FIGS. 2A to 2J.

First, the device isolation region 12 for defining a device region is formed on the semiconductor substrate 10 of, e.g., silicon by, e.g., STI (Shallow Trench Isolation).

Then, the wells 14a, 14b are formed by implanting a dopant impurity by ion implantation.

Next, by the usual method for forming transistors, transistors 24 each including the gate electrode (gate line) 18 and the source/drain regions 22a, 22b are formed in the device region defined by the device isolation region 12 (see FIG. 2A).

Then, the 200 nm-thickness SiON film 26, for example, is formed on the entire surface by, e.g., plasma CVD (Chemical Vapor Deposition). The SiON film 26 functions as the stopper film in planarization by CMP.

Then, the 1000 nm-thickness silicon oxide film 28, for example, is formed on the entire surface by, e.g., CVD.

Thus, the SiON film 26 and the silicon oxide film 28 form the inter-layer insulation film 30.

Next, the surface of the inter-layer insulation film 30 is planarized by, e.g., CMP (see FIG. 2B).

Then, by photolithography and etching, the contact holes 32a, 32b are formed in the inter-layer insulation film 30 down to the source/drain regions 22a, 22b (see FIG. 2C).

Next, as the degassing processing, thermal processing is made in, e.g., a nitrogen atmosphere at, e.g., 650° C. for, e.g., 30 minutes.

Then, the 20 nm-thickness Ti film, for example, is formed on the entire surface by, e.g., sputtering. Subsequently, the 50 nm-thickness TiN film, for example, is formed on the entire surface by, e.g., sputtering. Thus, the adhesion layer 34 of the Ti film and the TiN film sequentially laid is formed.

Then, as the conduction film 36 of a noble metal, a 400 nm-thickness Ir film, for example, is formed on the adhesion layer 34 by, e.g., MOCVD (see FIG. 2D). An iridium precursor as the raw material can be, e.g., Lewis base stabilized β-diketonate iridium composition, Lewis base stabilized β-ketoiminate iridium composition or others. Such iridium precursor is decomposed in the present of an oxidizing gas, e.g., O₂, O₃, N₂O or others to thereby deposit the Ir film. The deposition temperature is, e.g., below 500° C. excluding 500° C.

Then, on the conduction film 36, the ferroelectric film 42 of, e.g., a 120 nm-thickness PZT film is formed by, e.g., MOCVD.

In depositing the PZT film by MOCVD, a 3 mol % concentration of Pb(DPM)₂ (Pb(Cl₁₁H₁₉O₂)₂) solved in THF (tetrahydrofuran: C₄H₈O) liquid as an organic source for the Pb supply is fed into an evaporator at a 0.32 ml/min flow rate. As an organic source for the zirconium (Zr) supply, a 3 mol % concentration of Zr(dmhd)₄ (Zr(C₉H₁₅O₂)₄) solved in THF liquid is fed into the evaporator at a 0.2 ml/min flow rate. Furthermore, as an organic source for he titanium (Ti) supply, a 3 mol % concentration of Ti(O-iPr)₂(DPM)₂(Ti(C₃H₇O)₂(C₁₁H₁₉O₂)₂) solved in THF liquid is fed into the evaporator at a 0.2 ml/min flow rate. The evaporator is heated to, e.g., 260° C., and the above respective organic sources are evaporated in the evaporator. The respective evaporated organic sources are mixed with oxygen in the evaporator, then introduced into a shower head disposed at an upper part in the reactor and is ejected homogeneously in a single flow to the semiconductor substrate 10 opposed to the shower head. The partial pressure of oxygen in the reactor is, e.g., 5 Torr. The film depositing period of time is, e.g., 420 seconds. The composition of the PZT film deposited under these conditions was Pb/(Zr+Ti)=1.15, Zr/(Zr+Ti)=0.45.

Then, thermal processing is made in an atmosphere containing oxygen to thereby crystallize the ferroelectric film 42. Specifically, the following two-stage thermal processing, for example, is made. That is, as the first stage thermal processing, thermal processing of 600° C. substrate temperature and 90 seconds thermal processing period of time is made by RTA in an atmosphere of the mixed gas of oxygen and argon. Subsequently, as the second stage thermal processing, thermal processing of 750° C. and 60 seconds thermal processing period of time is made by RTA in an oxygen atmosphere.

Next, on the ferroelectric film 42, the upper electrode 44 of, e.g., a 200 nm-thickness IrO_{X} film is formed by, e.g., sputtering (see FIG. 2E).

Next, on the upper electrode 44, an insulation film 64 to be the hard mask which will be described later is formed. As the insulation film 64, a 200 nm-thickness TiN film and an 800 nm-thickness TEOS film, for example, are formed.

Next, by photolithography and etching, the insulation film 64 is patterned into the plane shape of the ferroelectric capacitors 46 (see FIG. 2F) Then, with the insulation film 64 as the hard mask, the upper electrode 44, the ferroelectric film 42, the conduction film. 36 and the adhesion layer 34 in the region which is not covered by the insulation film 64 are sequentially etched. After the etching, the insulation film 64, which has been used as the hard mask is removed (see FIG. 2G).

Thus, the ferroelectric capacitors 46 each including the lower electrode 38, the ferroelectric film 42 and the upper electrode 44 are formed. The lower electrodes 38 are formed of the conduction film 36 of a noble metal and the adhesion layer 34 and are integrated with the plug portions 38a buried in the contact holes 32a and connected to the source/drain regions 22a.

The plug 40 formed of the conduction film 36 of a noble metal and the adhesion layer 34, and connected to the source/drain region 22 is formed in the contact hole 32b.

Next, thermal processing of, e.g., 350° C. and 1 hour is made in a furnace containing oxygen. This thermal processing is for preventing the generation of release of the protection film 48 to be formed later.

Then, on the inter-layer insulation film 30 with the ferroelectric capacitors 46 formed on, the protection film 48 is formed by, e.g., sputtering or MOCVD (see FIG. 2H). The ferroelectric capacitors 46 are covered by the protection film 48. The protection film 48 is, e.g., a 20-100 nm-thickness Al₂O₃ film. The protection film 48 is for protecting the ferroelectric capacitors 46 from process damages, etc.

Next, thermal processing of, e.g., 550-650° C. and 60 minutes is made in a furnace containing oxygen. This thermal processing is for recovering the ferroelectric film 42 from damages made in forming the upper electrode 44 on the ferroelectric film 42 and the etching.

Next, the inter-layer insulation film 50 of, e.g., a 1500 nm-thickness TEOS film is formed on the entire surface by, e.g., CVD.

Then, the surface of the inter-layer insulation film 50 is planarized by, e.g., CMP (see FIG. 2I).

Then, in the inter-layer insulation film 50 and the protection film 48, the contact holes 52a are formed down to the upper electrodes 44 of the ferroelectric capacitors 46, and the interconnection trenches 54a connected to the contact holes 52a are formed in the inter-layer insulation film 50. In the inter-layer insulation film 50 and the protection film 48, the contact hole 52b is formed down to the plug 40, and the interconnection trench 54b connected to the contact hole 52b is formed in the inter-layer insulation film 50.

Next, in the contact holes 52a and the interconnection trenches 54a and in the contact hole 52b and the interconnection trench 54b, the barrier metal film 56 of, e.g., a 30 nm-thickness Ti film and a 50 nm-thickness TiN film is formed by, e.g., sputtering.

Then, the aluminum film 58 is buried in the contact holes 52a and the interconnection trenches 54a with the barrier metal film 56 formed in and in the contact hole 52b and the interconnection trench 54b with the barrier metal film 56 formed in.

Thus, by the usual interconnection forming steps, the interconnections 60a formed of the barrier metal film 56 and the aluminum film 58 are formed in the interconnection trenches 54a, and in the interconnection trench 54b, the interconnection 60b formed of the barrier metal film 56 and the aluminum film 58 is formed (see FIG. 2J). The interconnections 60a are connected to the upper electrodes 44 of the ferroelectric capacitors 46 by the plug portions 62a buried in the contact holes 52a. The interconnection 60b is connected to the plug 40 by the plug 52b buried in the contact hole 52b.

Hereafter, corresponding to a circuit design, etc., on the inter-layer insulation film 50 with the interconnections 60a, 60b formed in, an interconnection of a single layer or interconnections of plural layers are suitably formed by the usual interconnection forming steps.

Thus, the semiconductor device according to the present embodiment is manufactured.

As described above, according to the present embodiment, the lower electrode 38 includes the conduction film 36 of a noble metal and is integrated with the plug portion 38a connected to the source/drain region 22a, whereby the lower electrode 38 of a required orientation can be formed with high control in comparison with the case that a tungsten plug, which is liable to be oxidized, is formed separate from a lower electrode. Thus, the crystallinity of the ferroelectric film 42 formed on the lower electrode 38 can be improved, and the ferroelectric capacitor 46 can have good electric characteristics.

According to the present embodiment, the plug portion 38a connected to the source/drain region 22a is formed integral with the lower electrode 38, whereby the defective contact between the tungsten plug and the lower electrode caused in the conventional case in which both are formed separate from each other is never a problem.

According to the present embodiment, as the conduction film forming the lower electrode 38 including the plug portion 38a, the conduction film 36 of a noble metal, which is hard to be oxidized and remains low resistive even when oxidized, is formed, whereby good contact can be realized.

Furthermore, according to the present embodiment, the conduction film 36 formed of a noble metal whose oxide has the property of preventing the diffusion of hydrogen and water is formed, whereby as far as the noble metal conduction film 36 is oxidized, the arrival of hydrogen and water at the ferroelectric film 42 is prevented, and the reduction of the metal oxide forming the ferroelectric film 42 with hydrogen and water can be suppressed. Thus, the deterioration of the electric characteristics of the ferroelectric capacitor 46 can be suppressed.

(A Modification)

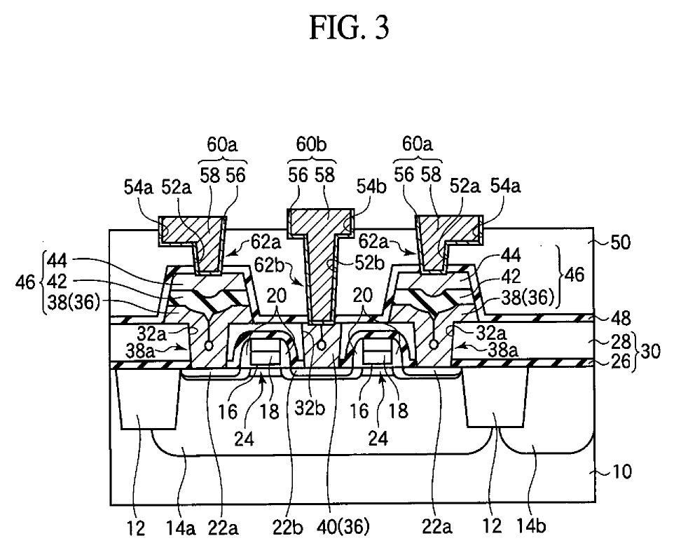

The semiconductor device according to a modification of the present embodiment will be explained with reference to FIG. 3. FIG. 3 is a sectional view showing the structure of the semiconductor device according to the present modification.

The semiconductor device according to the present modification is the semiconductor device described above which is free from the adhesion layer 34 for ensuring the adhesion to the base of the conduction film 36 of a noble metal.

As illustrated in FIG. 3, in the inter-layer insulation film 30, the contact holes 32a, 32b are formed down to the source/drain regions 22a, 22b.

In the contact hole 32a and on the inter-layer insulation film 30 around the contact hole 32a, the conduction film 36 of a noble metal is formed directly thereon. The noble metal conduction film 36 is formed directly in the contact hole 32b. The conduction film 36 is, e.g., a 400 nm-thickness Ir film.

Thus, the lower electrode 38 of the ferroelectric capacitor 46 is formed of the conduction film 36 of a noble metal. The lower electrode 38 is integrated with the plug portion 38a buried in the contact hole 32a and connected to the source/drain region 22a.

In the contact hole 32b, the plug 40 is formed of the conduction film 36 and connected to the source/drain region 22b.

On the lower electrode 38, as in the above, the ferroelectric film 42 and the upper electrode 44 are sequentially formed, and the ferroelectric capacitor 46 is formed of the lower electrode 38, the ferroelectric film 42 and the upper electrode 44.

As in the semiconductor device according to the present modification, the adhesion layer 34 for ensuring the adhesion of the conduction film 36 of a noble metal to the base may not be formed.

When the adhesion layer 34 is not formed, as is not in the semiconductor device according to the present modification, the conduction film 36 is formed of a noble metal oxide, whereby the conduction film 36 can function also as the film for preventing the diffusion of hydrogen and water. Such conduction film 36 prevents the arrival of hydrogen and water at the ferroelectric film 42, and the reduction of the metal oxide forming the ferroelectric film 42 with hydrogen and water can be suppressed. Thus, the deterioration of the electric characteristics of the ferroelectric capacitor 46 can be suppressed.

### A Second Embodiment

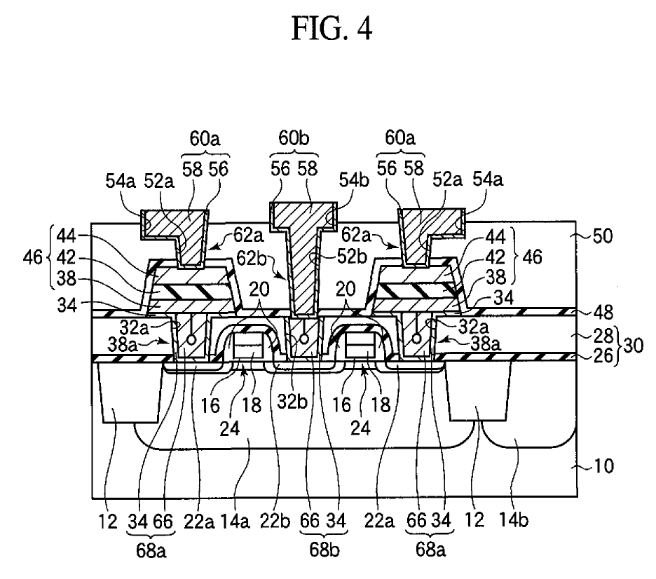

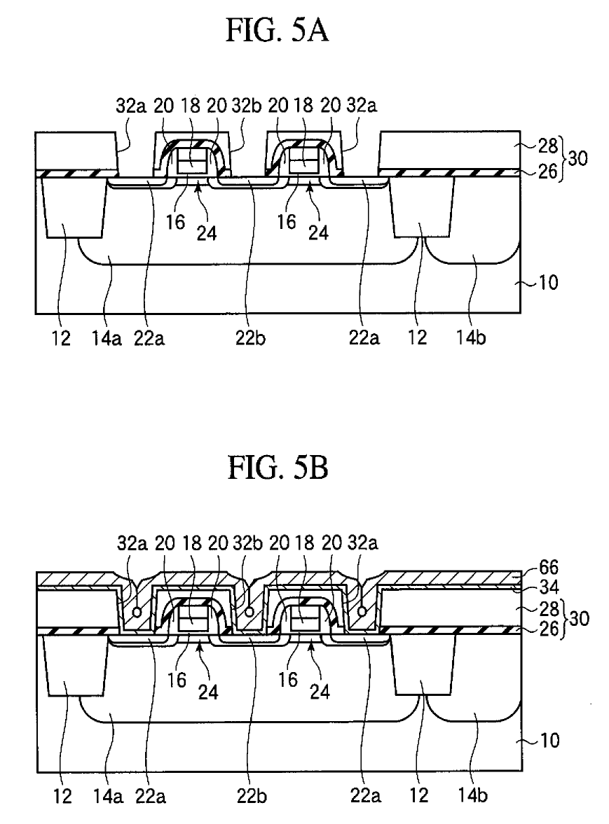

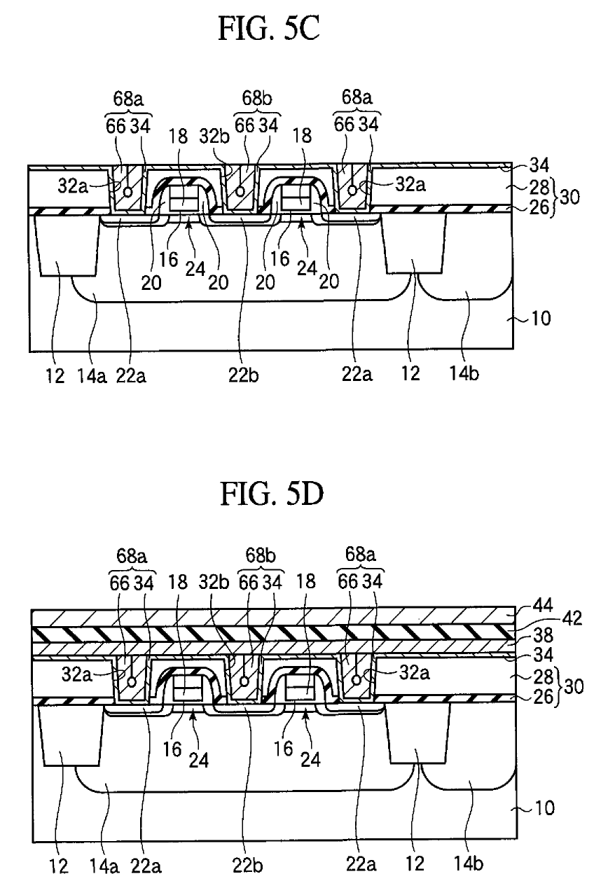

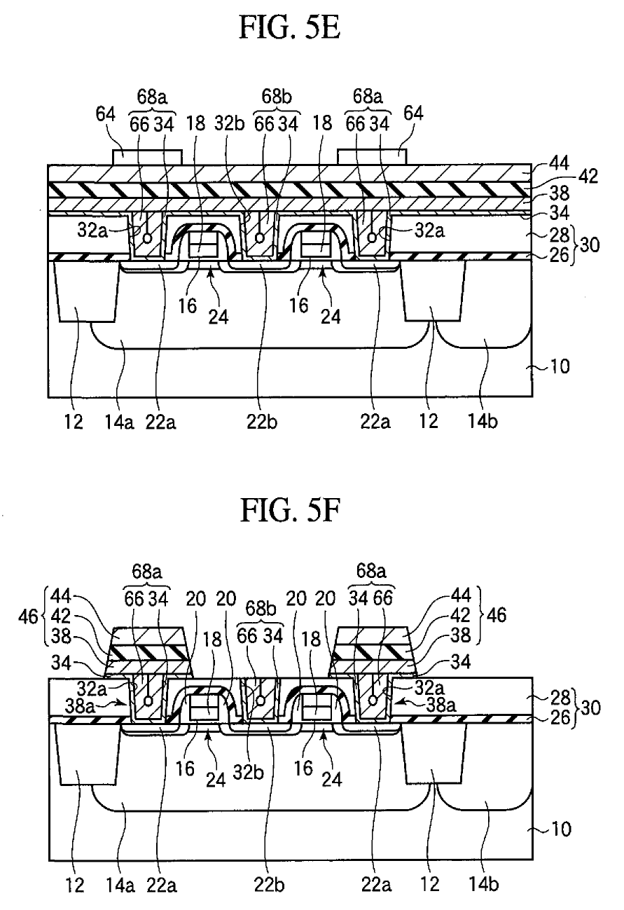

The semiconductor device and the method of manufacturing the same according to a second embodiment of the present invention will be explained with reference to FIGS. 4 to 5F. FIG. 4 is a sectional view showing the structure of the semiconductor device according to the present embodiment. FIGS. 5A to 5F are sectional views showing the method of manufacturing the semiconductor device according to the present embodiment. The same members of the present embodiment as those of the semiconductor device and the method of manufacturing the same according to the first embodiment are represented by the same reference numbers not to repeat or to simplify their explanation.

The basic structure of the semiconductor device according to the present embodiment is substantially the same as that of the semiconductor device according to the first embodiment. The semiconductor device according to the present embodiment is different from the semiconductor device according to the first embodiment in that the lower electrode 38 of ferroelectric capacitor 46, and the plug 68a electrically interconnecting the lower electrode 38 and source/drain region 22a are formed separate from each other. The structure of the semiconductor device according to the present embodiment will be explained with reference to FIG. 4.

As in the semiconductor device according to the first embodiment, a 200 nm-thickness SiON film 26, for example, and a 1000 nm-thickness silicon oxide film 28, for example, are sequentially laid on a semiconductor substrate 10 with transistors 24 formed on. Thus, an inter-layer insulation film 30 of the SiON film 26 and the silicon oxide film 28 sequentially laid is formed. The surface of the inter-layer insulation film 30 is planarized.

In the inter-layer insulation film 30, contact holes 32a, 32b are formed down to the source drain regions 22a, 22b.

On the inside wall of the contact hole 32a, on the source/drain region 22a at the bottom of the contact hole 32a and on the inter-layer insulation film 30 around the contact hole 32a, an adhesion layer 34 for ensuring the adhesion of a conduction film 66 of a noble metal and a lower electrode 38 which will be described later to the base is formed. On the inside wall of the contact hole 32b and the source/drain region 22b at the bottom of the contact hole 32b, the adhesion layer 34 for ensuring the adhesion of the noble metal conduction film 66 which will be described later to the base is formed. The adhesion layer 34 is formed of, e.g., a 20 nm-thickness Ti film and, e.g., a 50 nm-thickness TiN film sequentially laid. The adhesion layer 34 functions also as the barrier layer for preventing the diffusion of hydrogen and water. Such adhesion layer 34 prohibits the arrival of hydrogen and water at a ferroelectric film 42 to thereby suppress the reduction of the metal oxide forming the ferroelectric film 42 with hydrogen and water. Thus, the deterioration of the electric characteristics of a ferroelectric capacitor 46 can be suppressed.

In the contact hole 32a with the adhesion layer 34 formed in, the noble metal conduction film 66 is buried. In the contact hole 32b with the adhesion layer 34 formed in, the noble metal conduction film 66 is buried in. The conduction film 66 is, e.g., a 250 nm-thickness Ir film.

Thus, the adhesion layer 34 and the noble metal conduction film 66 are formed in the contact hole 32a. The surface of the conduction film 66 is planarized, and plug 68a connected to the source/drain region 22a is formed.

In the contact hole 32b, a plug 68b formed of the adhesion layer 34 and the noble metal conduction film 66 and connected to the source/drain region 22b is formed.

On the adhesion layer 34 formed on the inter-layer insulation film 30 around the contact hole 32a and on the conduction film 66 buried in the contact hole 32a, a lower electrode 38 of the ferroelectric capacitor 46 is formed. The lower electrode 38 is formed of a conduction film of a noble metal, specifically, e.g., a 50 nm-thickness platinum (Pt) film.

More preferably, the lower electrode is formed of the layered film of a 20 nm-thickness amorphous noble metal oxide film (e.g., platinum oxide (PtO_{X}) film and a 50 nm-thickness platinum (Pt) film. The amorphous noble metal oxide film (PtO_{X} film) can prevent the diffusion of Ir film into the ferroelectric film, and can suppress the leak current of the capacitor and further improve the crystallinity of the lower electrode. When the lower electrode thus include the adhesion layer of amorphous noble metal oxide film, the adhesion layer of the amorphous noble metal oxide film can be film of at least one of, e.g., oxides of Pt, Ir, Ru, Rh, Re, Os and Pd, and SrRuO₃. The lower electrode 38 is connected to the plug 68a. To further improve the crystallinity of the lower electrode, annealing of 750° C. and 60 sec is made by RTA in an Ar atmosphere.

On the lower electrode 38, the ferroelectric film 42 of the ferroelectric capacitor 46 is formed. The ferroelectric film 42 can be, e.g., 120 nm-thickness PZT film.

On the ferroelectric film 42, the upper electrode 44 of the ferroelectric capacitor 46 is formed. The upper electrode 44 can be, e.g., 200 nm-thickness IrO_{X} film.

Thus, the ferroelectric capacitors 46 each including the lower electrode 38, the ferroelectric film 42 and the upper electrode 44 are constituted.

On the inter-layer insulation film 30 with the ferroelectric capacitors 46 formed on, a protection film 48 for preventing the diffusion of hydrogen and water is formed. The protection film 48 is formed, covering the ferroelectric capacitors 46, i.e., covering the side surfaces of the adhesion layers 34 formed on the inter-layer insulation film 30, the side surfaces of the lower electrodes 38, the side surface of the ferroelectric films 42, the side surfaces of the upper electrodes 44 and the upper surfaces of the upper electrodes 44. The protection film 48 is, e.g., a 20-100 nm-thickness Al₂O₃ film. The protection film 48 prevents the arrival of hydrogen and water at the ferroelectric film 42 to thereby suppress the reduction of the metal oxide forming the ferroelectric film 42 with hydrogen and water. Thus, the deterioration of the electric characteristics of the ferroelectric capacitor 46 can be suppressed.

On the protection film 48, an inter-layer insulation film 50 of, e.g., a 1500 nm-thickness TEOS film is formed.

As in the semiconductor device according to the first embodiment, in the inter-layer insulation film 50 and the protection film 48, interconnections 60a connected to the upper electrodes 44 of the ferroelectric capacitors 46 and an interconnection 60b connected to the plug 68b are formed.

Thus, the semiconductor device according to the present embodiment is constituted.

The semiconductor device according to the present embodiment is characterized mainly in that the plug 68a formed below the lower electrode 38 of the ferroelectric capacitor 46 and electrically interconnecting the lower electrode 38 and the source/drain region 22a includes the conduction film 66 of a noble metal.

The plug 68a formed below the lower electrode 38 of the ferroelectric capacitor 46 includes the conductor film 66 of a noble metal, which is hard to be oxidized, whereby in comparison with the case that the tungsten plug is formed separate from the lower electrode, the lower electrode 38 of a required orientation can be formed with high control. In addition, the semiconductor device according to the present embodiment, in which the plug 68a and the lower electrode 38 are formed separate from each other, the lower electrode 38 is further flat in comparison with the semiconductor device according to the first embodiment. Thus, the crystallinity of the ferroelectric film 42 formed on the lower electrode 38 can be improved, and the ferroelectric capacitor 46 can have good electric characteristics.

In the semiconductor device according to the present embodiment, the plug 68a is formed of the conduction film 66 of a noble metal, and the lower electrode 38 formed on the plug 68a are also formed of a conduction film of a noble metal, whereby the adhesion between the plug 68a and the lower electrode 38 can be improved, and the occurrence of the film release can be prevented.

The conduction film 66 forming the plug 68a, which is formed of a noble metal, is hard to be oxidized and remains low resistive even when oxidized, whereby good contact can be realized.

Furthermore, the oxide of a noble metal forming the conduction film 66 has the property of preventing the diffusion of hydrogen and water. Accordingly, as far as the conduction film 66 of a noble metal is oxidized, the arrival of hydrogen and water at the ferroelectric film 42 can be suppressed, and the reduction of the metal oxide forming the ferroelectric film 42 with hydrogen and water can be suppressed. Thus, the deterioration of the electric characteristics of the ferroelectric capacitor 46 can be suppressed.

Thus, according to the present embodiment, an FeRAM of the stack type memory cell structure having good operational characteristics and high reliability can be provided.

Next, the method of manufacturing the semiconductor device according to the present embodiment will be explained with reference to FIGS. 5A to 5F.

The steps up to the step of forming, in the inter-layer insulation film 30, the contact holes 32a, 32b down to the source/drain regions 22a, 22b are the same as those of the method of manufacturing the semiconductor device according to the first embodiment illustrated in FIGS. 2A to 2C, and their explanation is omitted.

After the contact holes 32a, 32b have been formed (see FIG. 5A), thermal processing of, e.g., 650° C. and 30 minutes is made, as degassing processing, in, e.g., an nitrogen atmosphere.

Then, the 20 nm-thickness Ti film, for example, is formed on the entire surface by, e.g., sputtering. Subsequently, the 50 nm-thickness TiN film, for example, is formed on the entire surface by, e.g., sputtering. Thus, the adhesion layer 34 of the Ti film and the TiN film sequentially laid is formed.

Then, as the conduction film 66 of a noble metal, a 200 nm-thickness Ir film, for example, is formed on the adhesion layer 34 by, e.g., MOCVD (see FIG. 5B). An iridium precursor as the raw material can be, e.g., Lewis base stabilized β-diketonate iridium composition, Lewis base stabilized β-ketoiminate iridium composition or others. Such iridium precursor is decomposed in the present of an oxidizing gas, e.g., O₂, O₃, N₂O or others to thereby deposit the Ir film. The deposition temperature is, e.g., below 500° C. excluding 500° C.

Then, the conduction film 66 is polished by, e.g., CMP until the adhesion layer 34 on the inter-layer insulation film 30 is exposed to thereby bury the conduction film 66 in the contact holes 32a, 32b. Thus, the plug 68a formed of the adhesion layer 34 and the conduction film 66 of a noble metal and connected to the source/drain region 22a is formed in the contact hole 32a. The plug 68b formed of the adhesion layer 34 and the noble metal conduction film 66 and connected to the source/drain region 22b is formed in the contact hole 32b (see FIG. 5C).

Next, the lower electrode 38 of, e.g., a 20 nm-thickness platinum oxide (PtO_{X}) and a 50 nm-thickness Pt film are formed by, e.g., sputtering. To improve the crystallinity of the lower electrode, annealing of 750° C. and 60 sec is made by RTA in an Ar atmosphere.

Then, the ferroelectric film 42 of, e.g., a 120 nm-thickness PZT film is formed on the entire surface by, e.g., MOCVD

In depositing the PZT film by MOCVD, a 3 mol % concentration of Pb(DPM)₂ (Pb(C₁₁H₁₉O₂)₂) solved in THF liquid as an organic source for the Pb supply is fed into an evaporator at a 0.32 ml/min flow rate. As an organic source for the Zr supply, a 3 mol % concentration of Zr(dmnd)₄ solved in THF liquid is fed into the evaporator at a 0.2 ml/min flow rate. Furthermore, as an organic source for the Ti supply, a 3 mol % concentration of Ti(O-iPr)₂(DPM)₂ solved in THF liquid is fed into the evaporator at a 0.2 ml/min flow rate. The evaporator is heated to, e.g., 260° C., and the above respective organic sources are evaporated in the evaporator. The respective evaporated organic sources are mixed with oxygen in the evaporator, then introduced into a shower head disposed at an upper part in the reactor and is ejected homogeneously in a single flow to the semiconductor substrate 10 opposed to the shower head. The partial pressure of oxygen in the reactor is, e.g., 5 Torr. The film depositing period of time is, e.g., 420 seconds. The composition of the PZT film deposited under these conditions was Pb/(Zr+Ti)=1.15, Zr/(Zr+Ti)=0.45. This ferroelectric PZT film may be formed by RF sputtering or sol-gel process.

Then, thermal processing is made in an atmosphere containing oxygen to thereby crystallize the ferroelectric film 42. Specifically, the following two-stage thermal processing, for example, is made. That is, as the first stage thermal processing, thermal processing of 600° C. substrate temperature and 90 seconds thermal processing period of time is made by RTA in an atmosphere of the mixed gas of oxygen and argon. Subsequently, as the second stage thermal processing, thermal processing of 750° C. and 60 seconds thermal processing period of time is made by RTA in an oxygen atmosphere.

Next, on the ferroelectric film 42, the upper electrode 44 of, e.g., a 200 nm-thickness IrO_{X} film is formed by, e.g., sputtering (see FIG. 5D).

Next, on the upper electrode 44, an insulation film 64 to be the hard mask which will be described later is formed. As the insulation film 62, a 200 nm-thickness TiN film and an 800 nm-thickness TEOS film, for example, are formed.

Then, by photolithography and etching, the insulation film 64 is patterned into the plane shape of the ferroelectric capacitors 46 (see FIG. 5E).

Then, with the insulation film 64 as the hard mask, the upper electrode 44, the ferroelectric film 42, the conduction film 66 and the adhesion layer 34 in the region which is not covered by the insulation film 64 are sequentially etched. After the etching, the insulation film 64 which has been used as the hard mask is removed (see FIG. 5F).

Thus, the ferroelectric capacitors 46 each including the lower electrode 38, the ferroelectric film 42 and the upper electrode 44 are formed. The lower electrodes 38 are formed of the conduction film 36 of a noble metal.

Hereafter, the step of thermal processing before the formation of the protection film 48 to the step of forming the interconnections 60a, 60b are the same as those of the method of manufacturing the semiconductor device according to the first embodiment illustrated in FIGS. 2H to 2J, and their explanation is omitted.

As described above, according to the present embodiment, as the plug the lower electrode 38 is connected to, the plug 68a including the conduction film 66 of a noble metal is formed, whereby the lower electrode 38 of a required orientation can be formed with high control in comparison with the case that a tungsten plug, which are liable to be oxidized, is formed separate from a lower electrode. Thus, the crystallinity of the ferroelectric film 42 formed on the lower electrode 38 can be improved, and the ferroelectric capacitor 46 can have good electric characteristics.

According to the present embodiment, the plug 68a including the conduction film 66 of a noble metal is formed, and on the plug 68a, the lower electrode 38 including a conduction film of a noble metal is formed, whereby the adhesion between the plug 68a and the lower electrode 38 can be improved, and the occurrence of the film release can be prevented.

According to the present embodiment, as the conduction film forming the plug 68a, the conduction film 66 of a noble metal, which is hard to be oxidized and remains low resistive even when oxidized, whereby good contact can be realized.

Furthermore, according to the present embodiment, the conduction film 66 of a noble metal, whose oxide has the property of preventing the diffusion of hydrogen and water is provided, whereby as far as the noble metal conduction film 66 is oxidized, the arrival of hydrogen and water at the ferroelectric film 42 can be suppressed, and the reduction of the metal oxide forming the ferroelectric film 42 with hydrogen and water can be suppressed. Thus, the deterioration of the electric characteristics of the ferroelectric capacitor 46 can be suppressed.

(A Modification)

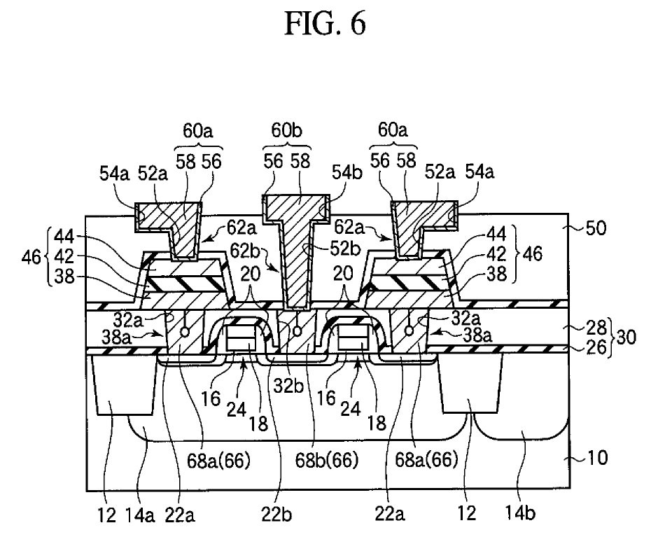

The semiconductor device according to a modification of the present embodiment will be explained with reference to FIG. 6. FIG. 6 is a sectional view showing the structure of the semiconductor device according to the present modification.

The semiconductor device according to the present modification is the semiconductor device described above which is free from the adhesion layer 34 for ensuring the adhesion to the base of the conduction film 66 of a noble metal.

As illustrated in FIG. 6, the contact holes 32a, 32b are formed in the inter-layer insulation film 30 down to the source/drain regions 22a, 22b.

In the contact hole 32a and on the inter-layer insulation film 30 around the contact hole 32a, the conduction film 66 of a noble metal is directly formed. In the contact hole 32b, the conduction film 66 of a noble metal is directly formed. The conduction film 66 is, e.g., a 250 nm-thickness Ir film.

Thus, in the contact hole 32a, the plug 68a formed of the conduction film 66, and planarized and connected to the source/drain region 22a is formed.

In the contact hole 32b, the plug 68b formed of the conduction film 66 and connected to the source/drain region 22b is formed.

On the inter-layer insulation film 30 around the contact hole 32a and on the conduction film 66 buried in the contact hole 32a, the lower electrode 38 of the ferroelectric capacitor 46 are formed. The lower electrode 38 is formed of a conduction film of a noble metal, specifically, e.g., a 50 nm-thickness Pt film. More preferably, the lower electrode are formed of the layered film of a 20 nm-thickness amorphous noble metal oxide film (e.g. platinum oxide (PtO_{X}) film, iridium oxide (IrO_{X}) film) and a 50 nm-thickness platinum (Pt) film. The lower electrode 38 is connected to the plug 68a.

As in the above, on the lower electrode 38, the ferroelectric film 42 and the upper electrode 44 are sequentially formed, and the ferroelectric capacitor 46 is formed of the lower electrode 38, the ferroelectric film 42 and the upper electrode 44.

As in the semiconductor device according to the present modification, the adhesion layer 34 for ensuring the adhesion of the conductor film 66 of a noble metal to the base may not be formed.

When the adhesion layer 34 is not formed, as is not in the semiconductor device according to the present modification, the conduction film 66 is formed of a noble oxide, as in the semiconductor device according to the modification of the first embodiment, whereby the conduction film 66 can function also as the film for preventing the diffusion of hydrogen and water. Such conduction film 66 prevents the arrival of hydrogen and water at the ferroelectric film 42, and the reduction of the metal oxide forming the ferroelectric film 42 with hydrogen and water can be suppressed. Thus, the deterioration of the electric characteristics of the ferroelectric capacitor 46 can be suppressed.

### A Third Embodiment

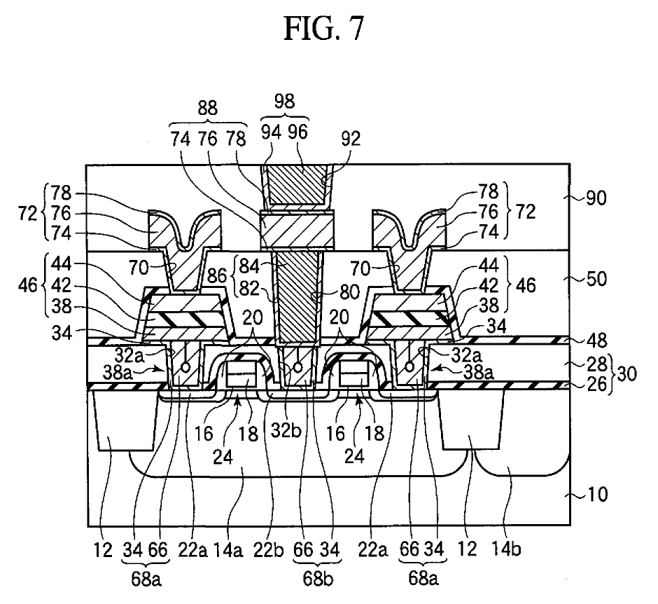

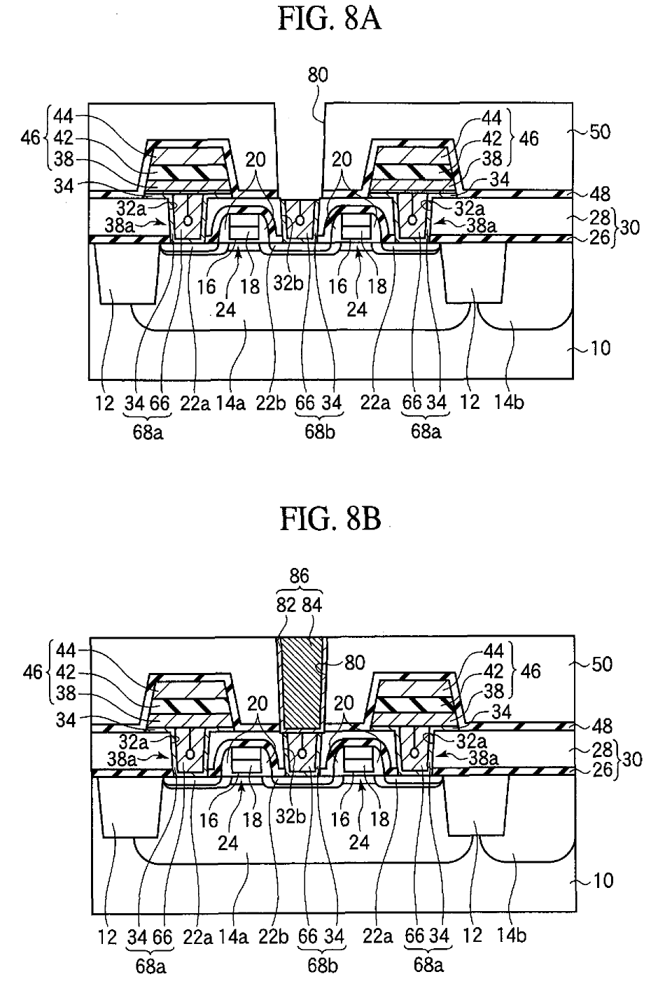

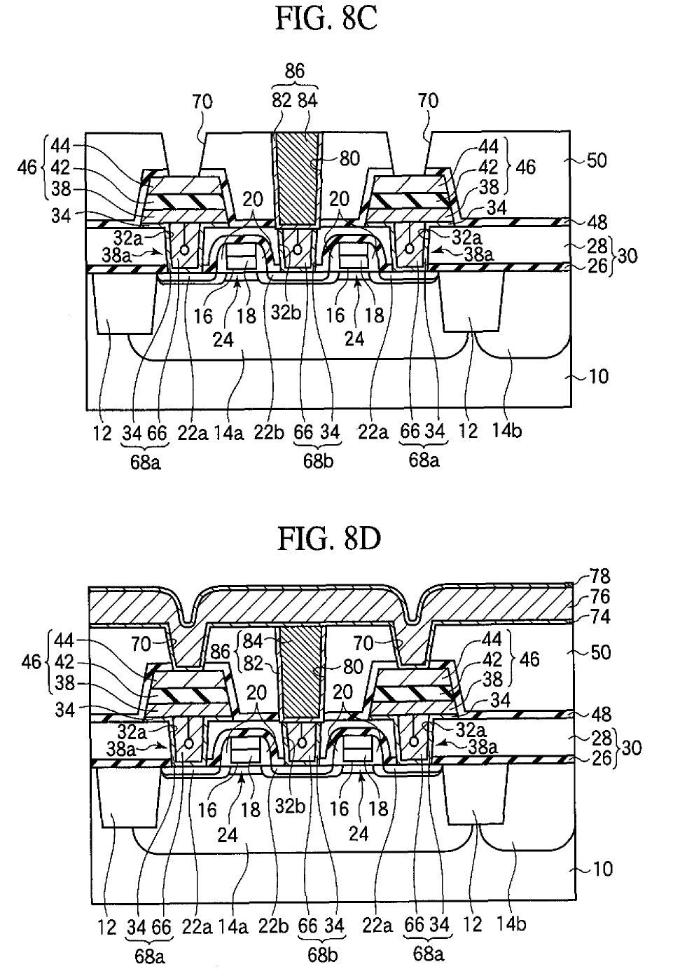

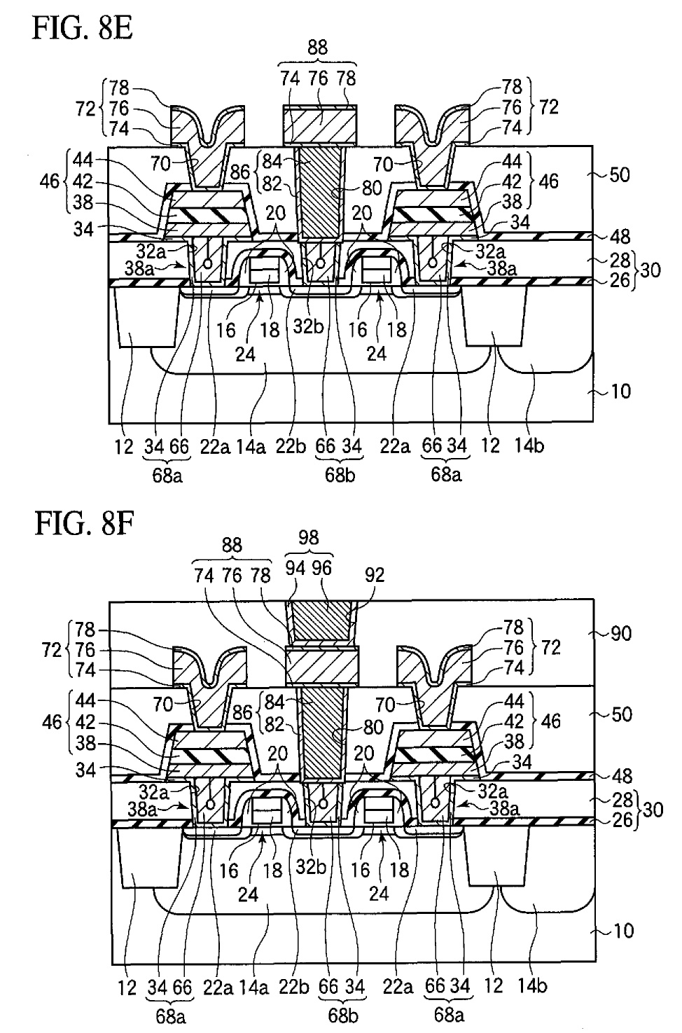

The semiconductor device and the method of manufacturing the same according to a third embodiment of the present invention will be explained with reference to FIGS. 7 to 8F. FIG. 7 is a sectional view showing the structure of the semiconductor device according to the present embodiment. FIGS. 8A to 8F are sectional views showing the method of manufacturing the semiconductor device according to the present embodiment. The same members of the present embodiment as those of the semiconductor device and the method of manufacturing the same according to the first and the second embodiments are represented by the same reference numbers not to repeat or to simplify their explanation.

The basic structure of the semiconductor device according to the present embodiment is substantially the same as that of the semiconductor device according to the second embodiment. The semiconductor device according to the present embodiment is different from the semiconductor device according to the second embodiment in that an interconnection 72 connected to the upper electrode 44 of the ferroelectric capacitor 46 includes a conduction film 76 of a noble metal. The structure of the semiconductor device according to the present embodiment will be explained with reference to FIG. 7.

As in the semiconductor device according to the second embodiment, on the inter-layer insulation film 30 with the ferroelectric capacitors 46 formed on, a protection film 48 for covering the ferroelectric capacitors 46, and an inter-layer insulation film 50 are sequentially formed.

In the inter-layer insulation film 50 and the protection film 48, contact holes 70 are formed down to the upper electrodes 44 of the ferroelectric capacitors 46. Interconnections (plate lines) 72 connected to the upper electrodes 44 of the ferroelectric capacitors 46 via the contact holes 70 are formed on the inter-layer insulation film 50. The interconnections 72 are formed of a barrier metal film 74, a conduction film 76 of a noble metal and a barrier metal film 78. The conduction film 76 of a noble metal is, e.g., a 200 nm-thickness Ir film.

The barrier metal films 74, 78 are the layered film of, e.g., a 75 nm-thickness TiN film, a 5 nm-thickness Ti film and a 75 nm-thickness TiN film sequentially laid.

The upper barrier metal layer 78 and the lower barrier metal layer 74 of the interconnections may be formed of the same material or different materials. For example, a single layer of Ti, Ta, TaN, TaSi, TiN, TiAlN, TiSi, etc. or a layered film of at least one or more of them can be used.

In the inter-layer insulation film 50 and the protection film 48, a contact hole 80 is formed down to the plug 68b. In the contact hole 80, a barrier metal film 82 formed of, e.g., a 20 nm-thickness Ti film and a 50 nm-thickness TiN film is formed. In the contact hole 80 with the barrier metal film 82 formed in, a tungsten film 84 is buried. Thus, a plug 86 formed of the barrier metal film 82 and the tungsten film 84 and connected to the plug 68b is formed in the contact hole 80.

On the inter-layer insulation film 50, an interconnection (bit line) 88 electrically connected to the source/drain region 22b via the plugs 86, 68b is formed. The interconnection 88 is formed of the barrier metal film 74, the conduction film 76 of a noble metal and the barrier metal film 78, as are the interconnections 72. Iridium (Ir) or iridium oxide (IrO_{X}) is used for the interconnection 88.

On the inter-layer insulation film 50 with the interconnections 72, 88 formed on, an inter-layer insulation film 90 is formed.

In the inter-layer insulation film 90, a contact hole 92 is formed down to the interconnection 88.

A barrier metal film 94 is formed in the contact hole 92. In the contact hole 92 with the barrier metal film 94 formed in, a tungsten film 96 is buried. Thus, in the contact hole 92, a plug 98 formed of the barrier metal film 94 and the tungsten film 96, and connected to the interconnection 88 is formed.

Thus, the semiconductor device according to the present embodiment is constituted.

The semiconductor device according to the present embodiment is characterized mainly in that the interconnection 72 connected to the upper electrode 44 of the ferroelectric capacitor 46 via the contact hole 70 includes the conduction film 76 of a noble metal.

Because of the noble metal conduction film 76 of the interconnection 72, the reaction between the upper electrode 44 formed of a noble metal or a noble metal oxide and the interconnection 72 can be suppressed, and the contact between the upper electrode 44 and the interconnection 72 can be good.

Furthermore, the noble metal oxide forming the conduction film 76 has the property of preventing the diffusion of hydrogen and water. Accordingly, as far as the noble metal conduction film 76 is oxidized, the arrival of hydrogen and water at the ferroelectric film 42 can be prevented, and the reduction of the metal oxide forming the ferroelectric film 42 with hydrogen and water can be suppressed. Thus, the deterioration of the electric characteristics of the ferroelectric capacitor 46 can be suppressed.

Thus, according to the present embodiment, an FeRAM of the stack type memory cell structure of good operational characteristics and high reliability can be provided.

Next, the method of manufacturing the semiconductor device according to the present embodiment will be explained with reference to FIGS. 8A to 8F.

The steps up to the step of forming the inter-layer insulation film 50 are the same as those of the method of manufacturing the semiconductor device according to the second embodiment, and the explanation is omitted.

After the inter-layer insulation film 50 is planarized, by photolithography and dry etching, the contact hole 80 is formed in the inter-layer insulation film 50 and the protection film 48 down to the plug 68b (see FIG. BA).

The barrier metal film 82 of, e.g., the 20 nm-thickness Ti film and the 50 nm-thickness TiN film is formed on the entire surface by, e.g., sputtering.

Then, the 500 nm-thickness tungsten film 84, for example, is formed on the entire surface by, e.g., CVD.

Then, the tungsten film 84 and the barrier metal film 82 are polished by, e.g., CMP until the surface of the inter-layer insulation film 50 is exposed. Thus, in the contact hole 80, the plug 86 formed of the barrier metal film 82 and the tungsten film 84 and connected to the plug 68b is formed (see FIG. 8B).

Next, an insulation film for preventing the oxidation of the W (tungsten) (not illustrated) is formed on the entire surface. The insulation film for preventing the oxidation of the W is, e.g., a SiON film.

Next, by photolithography and dry etching, the contact holes 70 are formed down to the upper electrodes 44 of the ferroelectric capacitors 46 in the insulation film for preventing the oxidation of the W, the inter-layer insulation film 50 and the protection film 48.

Next, by photolithography and dry etching, the contact holes 70 are formed in the inter-layer insulation film 50 and the protection film 48 down to the upper electrodes 44 of the ferroelectric capacitors 46.

Then, thermal processing of, e.g., 500° C. and 60 minutes is made in an oxygen atmosphere. This thermal processing is for expelling water in the inter-layer insulation film 50 around the capacitors and recovering the ferroelectric capacitors 46 from damages caused in the dry etching for forming the contact holes 70 to thereby recover the electric characteristics of the ferroelectric capacitors 46. After this annealing, the insulation film for preventing the oxidation of the tungsten is etched off (see FIG. SC).

Then, a 150 nm-thickness TiN film, for example, and a 5 nm-thickness Ti film, for example, are sequentially formed on the entire surface by, e.g., sputtering. Thus, the barrier metal film 74 of the TiN film and the Ti film sequentially laid is formed.

Then, as the conduction film 76 of a noble metal, a 300 nm-thickness Ir film, for example, is formed on the entire surface by, e.g., MOCVD.

Then, a 5 nm-thickness Ti film, for example, and a 150 nm-thickness Ti film, for example, are sequentially formed on the entire surface by, e.g., sputtering. Thus, the barrier metal film 78 of the Ti film and the Ti film sequentially laid is formed (see FIG. SD).

Next, by dry etching using a hard mask, the barrier metal film 78, the noble metal conduction film 76 and the barrier metal film 74 are patterned. Thus, the interconnections 72 formed of the barrier metal film 74, the noble metal conduction film 76 and the barrier metal film 78 and connected to the upper electrodes 44 via the contact holes 70 are formed (see FIG. 8E). The interconnection 78 formed of the barrier metal film 74, the noble metal conduction film 76 and the barrier metal film 78 and connected to the plug 86 is formed.

Hereafter, the inter-layer insulation film 90, the plug 98 connected to the interconnection 88, etc. are formed (see FIG. 8F), and corresponding to circuit designs, etc., a single layer or plural layers of interconnections are suitably formed by the usual interconnection forming steps.

Thus, the semiconductor device according to the present embodiment is manufactured.

As described above, according to the present embodiment, as the interconnection connected to the upper electrode 44 of the ferroelectric capacitor 46 via the contact hole 70, the interconnection 72 including the conduction film 76 of a noble metal, whereby the reaction between the upper electrode 44 of a noble metal or a noble metal oxide and the interconnection 72 can be suppressed, and the contact between the upper electrode 44 and the interconnection 72 can be good.

Furthermore, according to the present embodiment, the conduction film 76 is formed of a noble metal, whose oxide has the property of preventing the diffusion of hydrogen and water, whereby as far as the noble metal conduction film 76 is oxidized, the arrival of hydrogen and water at the ferroelectric film 42 can be prevented, and the reduction of the metal oxide forming the ferroelectric film 42 with hydrogen and water can be suppressed. Thus, the deterioration of the electric characteristics of the ferroelectric capacitor 46 can be suppressed.

The structure of the semiconductor device according to the present embodiment is substantially the same as that of the semiconductor device according to the second embodiment except the interconnections 72 connected to the upper electrodes 44 of the ferroelectric capacitors 46, but the structure except the interconnections 72 may be substantially the same as the structure of the semiconductor device according to the first embodiment.

Furthermore, the interconnection 72 can be the single layer interconnection 76 without the barrier metal layer 74 and the barrier metal layer 78.

### A Fourth Embodiment

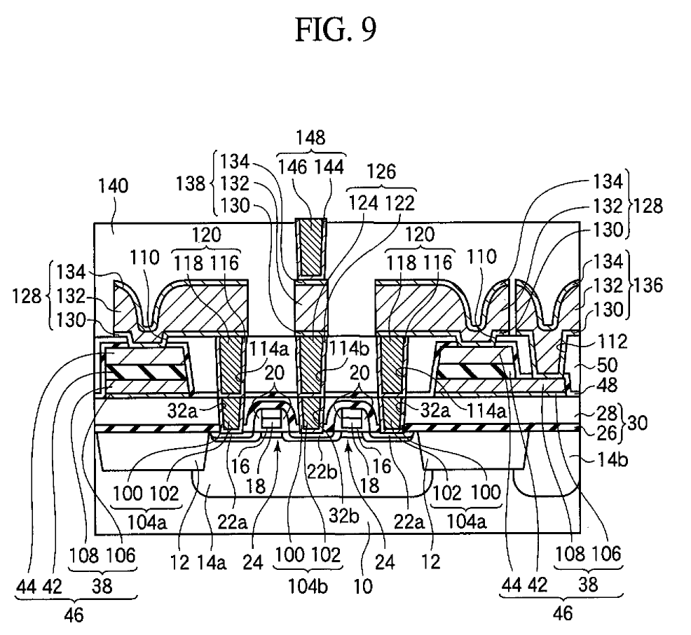

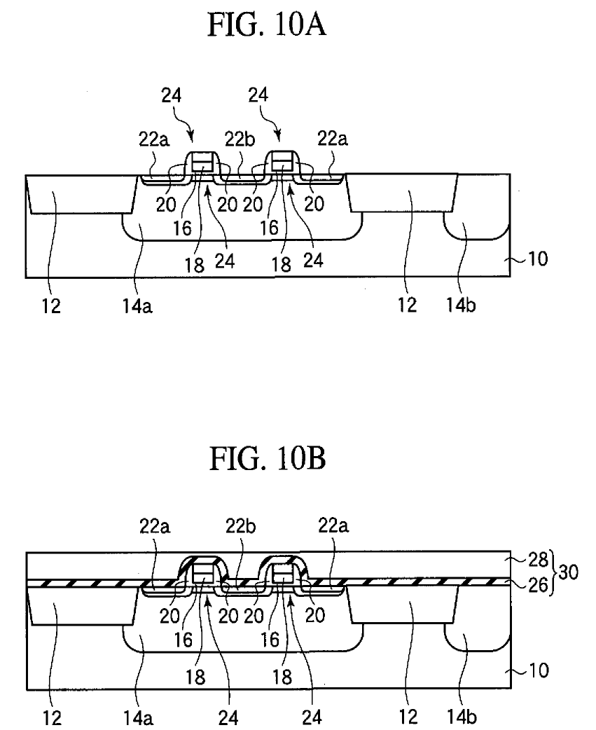

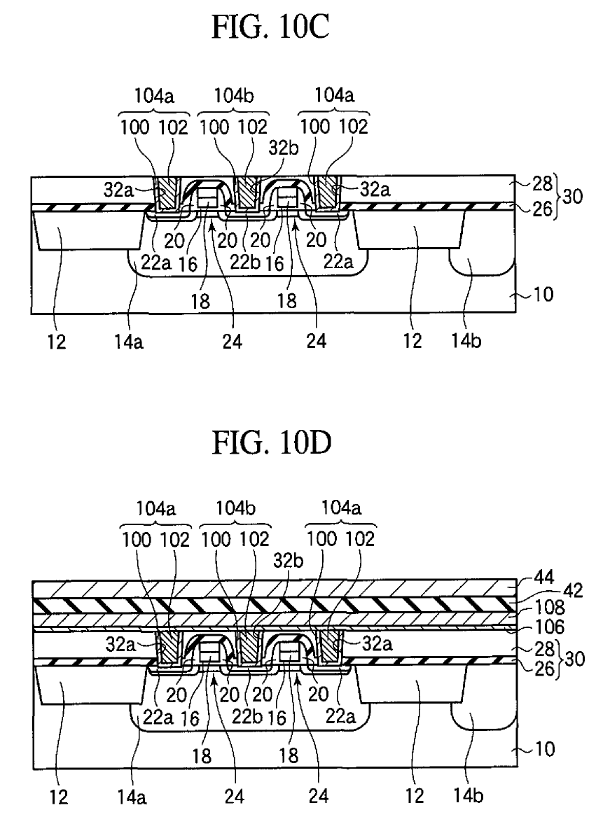

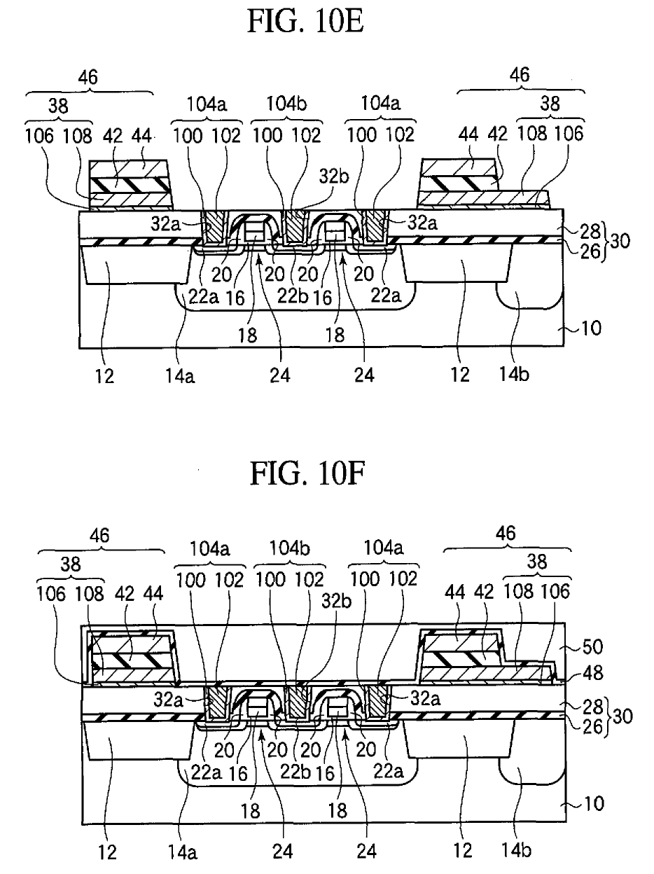

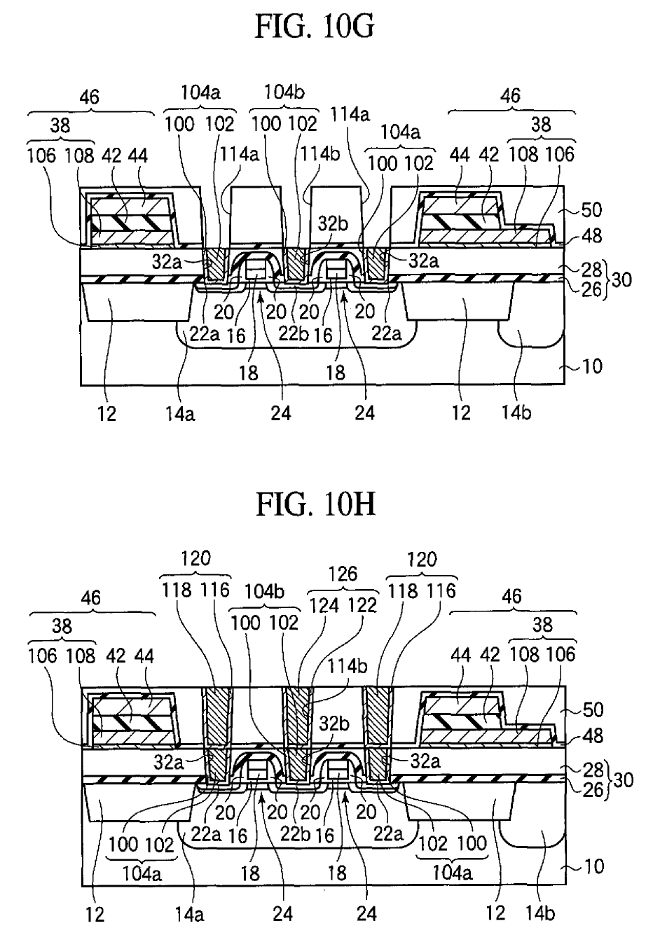

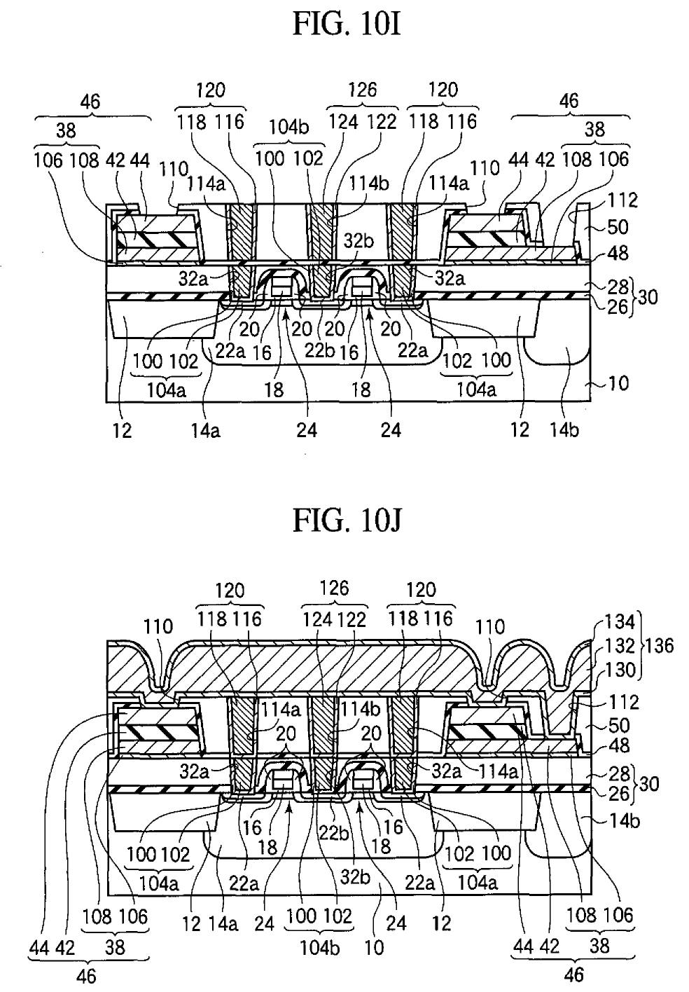

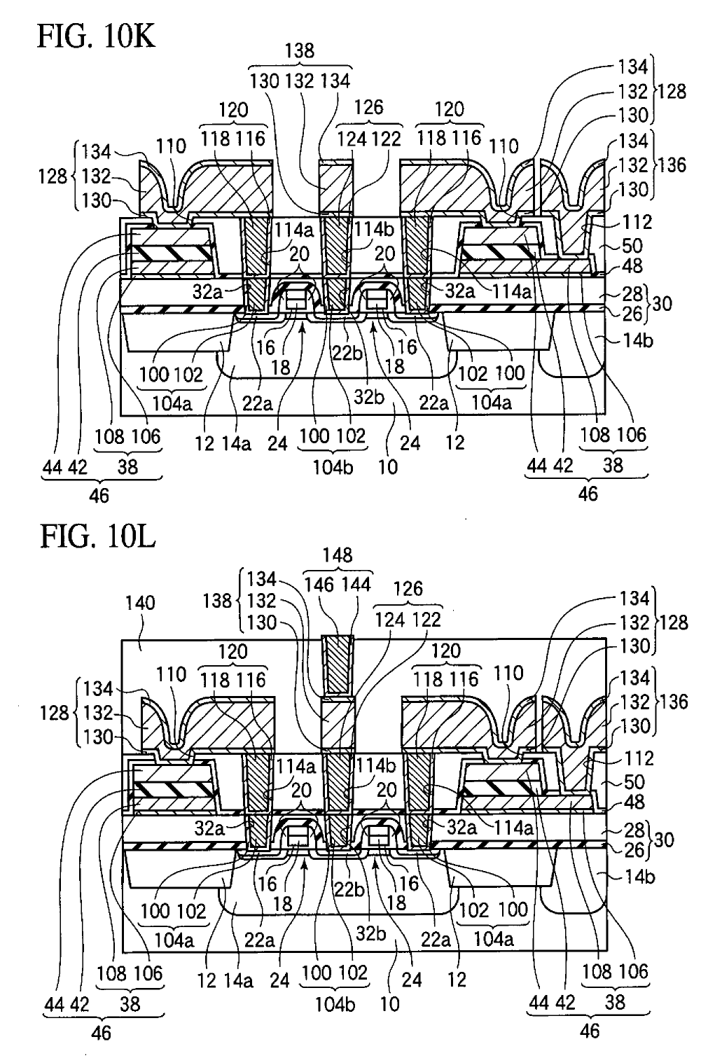

The semiconductor device and the method of manufacturing the same according to a fourth embodiment of the present invention will be explained with reference to FIGS. 9 to 10L. FIG. 9 is a sectional view showing the structure of the semiconductor device according to the present embodiment. FIGS. 10A to 10L are sectional views showing the method of manufacturing the semiconductor device according to the present embodiment. The same members of the present embodiment as those of the semiconductor device and the method of manufacturing the same according to the first embodiment are represented by the same reference numbers not to repeat or to simplify their explanation.

First, the structure of the semiconductor device according to the present embodiment will be explained with reference to FIG. 9. The semiconductor device according to the preset embodiment is an FeRAM of the planar type memory cell structure.

A device isolation region 12 for defining a device region is formed on a semiconductor substrate 10 of, e.g., silicon. The semiconductor substrate can be either of n-type and p-type. In the semiconductor substrate 10 with the device isolation region 12 formed on, wells 14a, 14b are formed.

On the semiconductor substrate 10 with the wells 14a, 14b formed in, gate electrodes (gate lines) 18 are formed with a gate insulation film 16 formed therebetween. A sidewall insulation film 20 is formed on the side wall of the gate electrode 18.

Source/drain regions 22a, 22b are formed on both sides of the gate electrode 18 with the sidewall insulation film 20 formed on.

Thus, transistors 24 each including the gate electrode 18 and the source/drain regions 22a, 22b are formed on the semiconductor substrate 10.

On the semiconductor substrate 10 with the transistors 24 formed on, a 200 nm-thickness SiON film 26, for example, and a 1000 nm-thickness silicon oxide film 28, for example, are sequentially laid. Thus, an inter-layer insulation film 30 of the SiON film 26 and the silicon oxide film 28 sequentially laid is formed. The surface of the inter-layer insulation film 30 is planarized.

In the inter-layer insulation film 30, contact holes 32a, 32b are formed down to the source/drain regions 22a, 22b.

In the contact holes 32a, 32b, a barrier metal film 100 of, e.g., a 50 nm-thickness TiN film is formed.

A tungsten film 102 is buried in the contact holes 32a, 32b with the barrier metal film 100 formed in.

Thus, in the contact holes 32a, 32b, plugs 104a, 104b formed of the barrier metal film 100 and the tungsten film 102 and connected to the source/drain regions 22a, 22b are formed.

On the inter-layer insulation film 30, lower electrodes 38 of ferroelectric capacitors 46 are formed the lower electrode 38 is formed of, e.g., a 20 nm-thickness Ti film 106 and, e.g., a 150 nm-thickness Pt film 108 sequentially laid. In place of the Ti film 106, titanium oxide (TiO_{X}) film, tantalum oxide (Ta₂O₅) film or Al₂O₃ film may be used.

On the lower electrode 38, a ferroelectric film 42 of the ferroelectric capacitor 46 is formed. The ferroelectric film 42 is, e.g., a 150 nm-thickness Pb_{1-X}La_{X}Zr_{1-Y}Ti_{Y}O₃ film (PLZT film).

On the ferroelectric film 42, an upper electrode 44 of the ferroelectric capacitor 46 is formed. The upper electrode 44 is formed of, e.g., a 200 nm-thickness iridium oxide (IrO_{X}) film.

Thus, the ferroelectric capacitors 46 each including the lower electrode 38, the ferroelectric film 42 and the upper electrode 44 are constituted.

On the inter-layer insulation film 30 with the ferroelectric capacitors 46 formed on, a protection film 48 for preventing the diffusion of hydrogen and water is formed. The protection film 48 is formed, covering the ferroelectric capacitors 46, i.e., covering the side surfaces of the lower electrodes 38, the side surface of the ferroelectric films 42, the side surfaces of the upper electrodes 44, and the upper surfaces of the upper electrodes 44 and the upper surfaces of the lower electrodes 38, where the ferroelectric film 42 is not formed. The protection film 48 is, e.g., a 50 nm-thickness Al₂O₃ film. The protection film 48 prevents the arrival of hydrogen and water at the ferroelectric film 42, and accordingly, the reduction of the metal oxide forming the ferroelectric film 42 with hydrogen and water can be suppressed. Thus, the deterioration of the electric characteristics of the ferroelectric capacitor 46 can be suppressed.

On the protection film 48, an inter-layer insulation film 50 of, e.g., a 1500 nm-thickness TEOS film. The surface of the inter-layer insulation film 50 is planarized.

In the inter-layer insulation film 50 and the protection film 48, contact holes 110 are formed down to the upper electrodes 44 of the ferroelectric capacitors 46. In the inter-layer insulation film 50 and the protection film 48, contact holes 112 are formed down to the lower electrodes 38 of the ferroelectric capacitors 46. In the inter-layer insulation film 50 and the protection film 48. Contact holes 114a, 114b are formed down to the plugs 104a, 104b.

In the contact holes 114a, 114b, a barrier metal film 116, 122 of a 20 nm-thickness Ti film, for example, and a 50 nm-thickness TiN film is formed. In the contact holes 114a, 114b with the barrier metal film 116, 122 formed in, a tungsten film 118, 124 is buried.

Thus, in the contact holes 114a, 114b, plugs 120, 126 formed of the barrier metal film 116, 122 and the tungsten film 118, 124 and connected to the plugs 104a, 104b are formed. The plugs 120 may be formed of a conduction film of a noble metal so as to prevent the eutectic reaction with the interconnections.

On the inter-layer insulation film 50, interconnections 128 connected to the upper electrodes 44 of the ferroelectric capacitors 46 via the contact holes 110, and connected to the plugs 120 are formed. The interconnections 128 are formed of a barrier metal film 130, a conduction film 132 of a noble metal and a barrier metal film 134.

On the inter-layer insulation film 50, interconnections (plate lines) 136 connected to the lower electrodes 38 of the ferroelectric capacitors 46 via the contact holes 112 are formed. The interconnections 136 are formed of the barrier metal film 130, the noble metal conduction film 132 and the barrier metal film 134.

On the inter-layer insulation film 50, an interconnection 138 connected to the plug 126 is formed. The interconnection 138 is formed of the barrier metal film 130, the noble metal conduction film 132 and the barrier metal film 134.

The noble metal conduction film 132 forming the interconnections 128, 136, 138 is, e.g., a 200 nm-thickness Ir film. The barrier metal film 130 forming the interconnections 128, 136, 138 is the layered film of, e.g., a 150 nm-thickness TiN film and a 5 nm-thickness Ti film sequentially formed. The barrier metal film 134 forming the interconnections 128, 136, 138 is the layered film of, e.g., a 5 nm-thickness Ti film and a 150 nm-thickness TiN film sequentially formed.

The interconnections 128, 136, 138 may be an interconnection 132 of a single layer without the barrier metal film 130 and the barrier metal film 134.

On the inter-layer insulation film 50 with the interconnections 128, 136, 138 formed on, an inter-layer insulation film 140 of, e.g., a 2600 nm-thickness TEOS film is formed.

A contact hole 142 is formed in the inter-layer insulation film 140 down to the interconnection 138. A barrier metal film 144 is formed in the contact hole 142. In the contact hole 142 with the barrier metal film 144 formed in, a tungsten film 146 is buried in. Thus, in the contact hole 142, a plug 148 formed of the barrier metal film 144 and the tungsten film 146 and connected to the interconnection 138 is formed.

On the inter-layer insulation film 140, an interconnection (bit line) (not illustrated) connected to the plug 148 is formed.

Thus, the semiconductor device according to the present embodiment is constituted.

The semiconductor device according to the present embodiment is characterized mainly in that the interconnection 128 connected to the upper electrode 144 of the ferroelectric capacitor 46 via the contact hole 110, and the interconnection 136 connected to the lower electrode 38 of the ferroelectric capacitors 46 via the contact hole 112 include of the conduction film 132 of a noble metal.

Because of the noble metal conduction film 132 included in the interconnections 128, 136, the reaction between the upper electrode 44 and the lower electrode 38 of a noble metal or a noble metal oxide and the interconnections 128, 136 can be suppressed. The contacts between the upper electrode 44 and the lower electrode 38 and the interconnections 128, 136 can be good.

The oxide of a noble metal forming the conduction film 132 has the property of preventing the diffusion of hydrogen and water. Accordingly, as far as the conduction film 132 of a noble metal is oxidized, the arrival of hydrogen and water at the ferroelectric film 42 can be prevented, and the reduction of the metal oxide forming the ferroelectric film 42 can be suppressed. Thus, the deterioration of the electric characteristics of the ferroelectric capacitor 46 can be suppressed.

Thus, according to the present embodiment, an FeRAM of the planar type memory cell structure having good operational characteristics and high reliability can be provided.

Next, the method of manufacturing the semiconductor device according to the present embodiment will be explained with reference to FIGS. 10A to 10L.

First, the device isolation region 12 for defining a device region is formed on the semiconductor substrate of, e.g., silicon by, e.g., STI.

Next, the wells 14a, 14b are formed by implanting a dopant impurity by ion implantation.

Then, by the usual method for forming transistors, transistors 24 each including the gate electrode (gate line) 18 and the source/drain regions 22a, 22b are formed in the device region defined by the device isolation regions 12 (see FIG. 10A).

Next, the 200 nm-thickness SiON film 26, for example, is formed on the entire surface by, e.g., plasma CVD. The SiON film 26 functions as the stopper film in the planarization by CMP.

Next, the 1000 nm-thickness silicon oxide film 28, for example, is formed on the entire surface by, e.g., CVD.

Thus, the inter-layer insulation film 30 of the SiON film 26 and the silicon oxide film 28 is formed.

Then, the surface of the inter-layer insulation film 30 is planarized by, e.g., CMP (see FIG. 10B).

Next, by photolithography and etching, the contact holes 32a, 32b are formed in the inter-layer insulation film 30 down to the source/drain regions 22a, 22b.

Next, the barrier metal film 100 of, e.g., a 50 nm-thickness TiN film is formed on the entire surface by, e.g., sputtering.

Next, on the entire surface, the 300 nm-thickness tungsten film 102, for example, is formed by, e.g., CVD.

Next, the tungsten film 102 and the barrier metal film 100 are polished by, e.g., CMP until the surface of the inter-layer insulation film 30 is exposed, so as to bury the tungsten film 102 in the contact holes 32a, 32b. Thus, in the contact holes 32a, the plugs 104a formed of the barrier metal film 100 and the tungsten film 102 and connected to the source/drain regions 22a are formed. In the contact hole 32b, the plug 104b formed of the barrier metal film 100 and the tungsten film 102 and connected to the source/drain region 22b is formed (see FIG. 10C).

Next, the 20 nm-thickness Ti film 106, for example, is formed on the entire surface by, e.g., sputtering.

Next, the 150 nm-thickness Pt film 108, for example, is formed on the Ti film 106 by, e.g., sputtering.

Next, on the Pt film 108, the ferroelectric film 42 of, e.g., a 150 nm-thickness PLZT film is formed by, e.g., sputtering.

Next, prescribed thermal processing is made to crystallize the ferroelectric film 42.

Next, on the ferroelectric film 42, the upper electrode 44 of, e.g., a 200 nm-thickness IrO_{X} film by, e.g., sputtering (see FIG. 10D).

Then, by photolithography and dry etching, the upper electrode 44, the ferroelectric film 42, the Pt film 108 and the Ti film 106 are patterned stage by stage (see FIG. 10E).

Thus, the ferroelectric capacitors 46 each including the lower electrode 38, the ferroelectric film 42 and the upper electrode 44 are formed. The lower electrode 38 is formed of the Ti film 106 and the Pt film 108.

Next, on the inter-layer insulation film 30 with the ferroelectric capacitors 42 formed on, the protection film 48 is formed by, e.g., sputtering or MOCVD. The ferroelectric capacitors 46 are covered by the protection film 48. The protection film 48 is, e.g., a 50 nm-thickness Al₂O₃ film. The protection film 48 is for protecting the ferroelectric capacitors 46 from process damages, etc.

Next, thermal processing of, e.g., 650° C. and 60 minutes is made in a furnace containing oxygen. This thermal processing is for recovering the ferroelectric film 42 from damages made in forming the upper electrodes 44 on the ferroelectric film 42 and the etching.

Next, the inter-layer insulation film 50 of, e.g., a 1500 nm-thickness TEOS film is formed on the entire surface by, e.g., CVD.

Next, the surface of the inter-layer insulation film 50 is planarized by, e.g., CMP (see FIG. 10F).

Then, by photolithography and etching, the contact holes 114a, 114b are formed in the inter-layer insulation film 50 and the protection film 48 down to the plugs 104a, 104b (see FIG. 10G).

Then, on the entire surface, the barrier metal film 116, 122 of, e.g., a 20 nm-thickness Ti film and a 50 nm-thickness TiN film is formed by, e.g., sputtering.

Next, on the entire surface, the 500 nm-thickness tungsten film 118, 124 is formed by, e.g., CVD.

Then, the tungsten film 118, 124 and the barrier metal film 116, 122 are polished by, e.g., CMP until the surface of the inter-layer insulation film 50 is exposed, so as to bury the tungsten film 118, 124 in the contact holes 114a, 114b. Thus, the plugs 120, 126 formed of the barrier metal film 116, 122 and the tungsten film 118, 124 and connected to the plugs 104a, 104b are formed in the contact holes 114a, 114b (see FIG. 10H).

Next, an insulation film for preventing the oxidation of the tungsten is formed on the entire surface. The insulation film for preventing the oxidation of the tungsten is, e.g., SiON film.

Then, by photolithography and dry etching, in the inter-layer insulation film 50 and the protection film 48, the contact holes 110 and the contact holes 112 are formed respectively down to the upper electrodes 44 of the ferroelectric capacitors 46 and down to the lower electrodes 38 of the ferroelectric capacitors 46.

Next, the thermal processing of, e.g., 550° C. and 60 minutes is made in an oxygen atmosphere. This thermal processing is for recovering the ferroelectric capacitors 46 from damages caused in the dry etching for forming the contact holes 110, 112 to recover the electric characteristics of the ferroelectric capacitors 46. After this annealing, the insulation film for preventing the oxidation of the tungsten (not illustrated) is etched back to be removed (see FIG. 10I).

Then, a 150 nm-thickness TiN film, for example, and a 5 nm-thickness Ti film, for example, are sequentially formed on the entire surface by, e.g., sputtering. Thus, the barrier metal film 130 of the TiN film and the Ti film sequentially laid is formed.

Next, as the conduction film 132 of a noble metal, a 200 nm-thickness Ir film, for example, is formed on the entire surface by, e.g., MOCVD.

Next, a 5 nm-thickness Ti film, for example, and a 150 nm-thickness TiN film, for example, are sequentially formed on the entire surface by, e.g., sputtering. Thus, the barrier metal film 134 of the Ti film and the TiN film sequentially laid is formed (see FIG. 10J).

Then, by dry etching using a hard mask, the barrier metal film 134, the noble metal conduction film 132 and the barrier metal film 130 are patterned. Thus, the interconnections 128 connected to the upper electrodes 44 via the contact holes 110 and connected to the plugs 120 are formed on the inter-layer insulation film 50. The interconnections 136 connected to the lower electrodes 38 via the contact holes 112 are formed. The interconnection 138 connected to the plug 126 is formed (see FIG. 10K). The interconnections 128, 136, 138 are formed of the barrier metal film 130, noble metal conduction film 132 and the barrier metal film 134.

Hereafter, the inter-layer insulation film 140, the plug 148 connected to the interconnection 138, etc. are formed (see FIG. 10L), and corresponding to circuit designs, etc., a single-layer or plural layers of interconnections are suitably formed by the usual interconnection forming steps.

Thus, the semiconductor device according to the present embodiment is manufactured.

As described above, according to the present embodiment, as the interconnection connected to the upper electrode 44 of the ferroelectric capacitor 46 via the contact hole 110 and the interconnection connected to the lower electrode 38 of the ferroelectric capacitor 46 via the contact hole 112, the interconnections 128, 136 including the noble metal conduction film 132 are formed, whereby the reaction between the upper electrode 44 and the lower electrode 38 of a noble metal or a noble metal oxide, and the interconnections 128, 136 can be suppressed, and the contacts between the upper electrodes 44 and the lower electrodes, and the interconnections 128, 136 can be good.

Furthermore, according to the present embodiment, the conduction film 132 of a noble metal, whose oxide has the property of preventing the diffusion of hydrogen and water, is formed, whereby as far as the noble metal of the conduction film 132 is oxidized, the arrival of hydrogen and water at the ferroelectric film 42 is prevented, and the reduction of the metal oxide forming the ferroelectric film 42 with hydrogen and water can be suppressed. Thus, the deterioration of the electric characteristics of the ferroelectric capacitor 46 can be suppressed.

### Modified Embodiments

The present invention is not limited to the above-described embodiments and can cover other various modifications.

For example, in the above-described embodiments, the ferroelectric film 42 is PZT film or PLZT film. However, the ferroelectric film 42 is not essentially PZT film or others, and can be any other ferroelectric film. For example, the ferroelectric film 42 can be, other than PZT film and PLZT film, PZT film or others, doped with a trace of La, Ca, Sr, Si or others, which has the perovskite crystal structure expressed by the general formula ABO₃ or SrBi₂Ta₂O₉ film (SBT film), (Bi_{X}La_{1-X})₄Ti₃O₁₂ film (BLT film), SrBi₂(Ta_{X}Nb_{1-X})₂O₉ film (SBTN film) or others, which has the crystal structure of the bismuth layered structure.

In the above-described embodiments, the ferroelectric film 42 is formed by MOCVD and sputtering but is not formed essentially by them. The process for forming the ferroelectric film 42 can be, other than CVD, such as MOCVD, etc., and sputtering, sol-gel process, MOD (Metal Organic Deposition), etc.

In the above-described embodiments, the ferroelectric film 42 is used. However, the present invention is applicable to manufacturing, e.g., DRAM, etc. using high dielectric film in place of the ferroelectric film 42. The high dielectric film can be, e.g., (BaSr)TiO₃ film (BST film), SrTiO₃ film (STO film), Ta₂O₅ film or others. The high dielectric film is a dielectric film whose relative dielectric constant is higher than that of silicon dioxide.

In the above-described embodiments, the conduction film 36 forming the lower electrode 38, the conduction film 66 forming the via 68a, the conduction film 76 forming the interconnection 72 connected to the upper electrode 44, and the conduction film 132 forming the interconnections 128, 136 connected to the upper electrode 44 or the lower electrode 38 are formed of noble metals. These conduction films 36, 66, 76, 132 may be formed of noble metal oxides. The conduction films 36, 66, 76, 132 can be films of at lest one substance selected out of, e.g., Pt, Ir, ruthenium (Ru), Rhodium (Rh), Rhenium (Re), osmium (Os), palladium (Pd) and their oxides. Layered films of these noble metals and noble metal oxides can be used as the conduction films 36. 66, 76, 132.

In forming the conduction films of these noble meals or noble metal oxides by MOCVD, the following precursors of the noble metals can be used. As the precursor of Pt, trimethyl(cyclopentadienyl)Pt(IV), trimethyl(β-diketonate)Pt(IV), bis(β-diketonate)Pt(II), tetrakis(trifluorophosphine)Pt(0) or others, for example, can be used. As the precursor of Ru, bis(cyclopentadienyl)Ru, tris(tetramethyl-3,5-heptadionate)Ru or others, for example, can be used. As the precursor of Pd, palladium bis(β-diketonate) or others, for example, can be used. As the precursor of Ph, Lewis base stabilized rhodium(I)β-diketonate or others, for example, can be used. When the conduction films are formed of the noble metal oxides, the conductions films may be formed at a higher film forming temperatures than when the conduction films are formed of the noble metals. For example, in the above-described embodiments, the Ir film is formed at a film forming temperature of below 550° C. excluding 550° C., but the film forming temperature is set at 550° C. including 550° C., whereby IrO_{X} film can be formed.

In the above-described embodiments, the conduction films 36, 66, 76, 132 are formed by MOCVD but are not formed essentially by MOCVD. The conduction films 36, 66, 76, 132 of noble metal or noble metal oxide can be formed by, other than MOCVD, CVD, e.g., LSCVD (Liquid Source Chemical Vapor Deposition) or others, CSD (Chemical Solution Deposition), or others.

In the above-described embodiments, the adhesion layer 34 is formed of the layered film of Ti film and TiN film but is not essentially formed of them. The adhesion layer 34 can be, e.g., Ti film, TiN film, TiAlN (titanium aluminum nitride) film, Ir film, IrO_{X} film, Pt film, Ru film, Ta film or others. A layered film of them may be used as the adhesion layer 34.

In the above second to the fourth embodiments, the lower electrode 38 is formed of Pt film. The conduction film forming the lower electrode is not essentially Pt film, and conduction films of various noble metals or noble metal oxides can be used. The conduction film forming the lower electrode 38 can be formed of at least one of, e.g., Pt, Ir, Ru, Rh, Re, Os, Pd and their oxides. As the conduction film forming the lower electrode 38, SrRuO₃ film (SRO film) can be used. A layered film of them may be used as the conduction film forming the lower electrode 38.

In the above-described embodiments, the upper electrode 44 is IrO_{X} film. However, the conduction film forming the upper electrode 44 is not limited to IrO_{X} film and can be various noble metals and noble metal oxides. The conduction film forming the upper electrode 44 can be, other than IrO_{X} film, a film of at least one of, e.g., Pt, Ir, Ru, Rh, Re, Os, Pd and their oxides. The conduction film forming the upper electrode 44 can be SRO film. A layered film of them may be used as the conduction film forming the upper electrode 44.

In the third and the fourth embodiments, the barrier metal film 74, 130 formed between the upper electrode 44 or the lower electrode 38, etc. and the conduction film 76, 132 is the layered film of TiN film, Ti film, and TiN film sequentially laid but is not limited to it. The barrier metal film 74, 130 can be the film of at least one of, Ti, TiN, TiAlN, Pt, Ir, IrO_{X}, Ru and Ta. The barrier metal film 74, 130 can be a layered film of them.

In the above-described embodiments, the plug portion 38a of the lower electrode 38 and the plug 68a the lower electrode 38 connected to are connected to the source/drain region 22a of the transistor 24. However, the present invention is applicable to cases that the plug portion 38a and the plug 68a are connected to various semiconductor elements.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A semiconductor device comprising:
a semiconductor element formed over a semiconductor substrate;
an insulation film formed over the semiconductor substrate with the semiconductor element formed over;
a plug buried in a contact hole formed in the insulation film down to the semiconductor element, connected to the semiconductor element, and including a conduction film of a noble metal or a noble oxide; and
a capacitor including a lower electrode formed over the insulation film with the plug formed in and connected to the plug, a dielectric film formed over the lower electrode and formed of a ferroelectric film or a high dielectric film, and an upper electrode formed over the dielectric film.

2. A semiconductor device according to claim 1, wherein
the conduction film is planarized.

3. A semiconductor device according to claim 2, further comprising:
an amorphous noble metal oxide adhesion layer formed over the insulation film with the plug formed in and connected to the plug,
wherein the lower electrode is formed on the amorphous noble metal oxide adhesion layer.

4. A semiconductor device according to claim 1, wherein
the plug is formed integral with the lower electrode.

5. A semiconductor device according to claim 1, further comprising
an adhesion layer formed in the contact hole, for ensuring the adhesion of the conduction film to a base.

6. A semiconductor device according to claim 1, further comprising:
another insulation film formed over said insulation film and the capacitor; and
an interconnection formed over said another insulation film, connected to the upper electrode via a contact hole formed in said another insulation film down to the upper electrode, and including a conduction film of a noble metal or a noble metal oxide.

7. A semiconductor device comprising:
a capacitor formed over a semiconductor substrate, and including a lower electrode, a dielectric film formed over the lower electrode and formed of a ferroelectric film or a high dielectric film, and an upper electrode formed over the dielectric film;
an insulation film formed over the semiconductor substrate and the capacitor; and
an interconnection formed over the insulation film, connected to the upper electrode or the lower electrode via a contact hole formed in the insulation film down to the upper electrode or the lower electrode, and including a conduction film of a noble metal or a noble metal oxide.

8. A semiconductor device according to claim 1, wherein
the conduction film of the plug includes a film of at least one material selected from the group consisting of Pt, Ir, Ru, Rh, Re, Os, Pd and their oxides.

9. A semiconductor device according to claim 7, wherein
the conduction film of the interconnection includes a film of at least one material selected from the group consisting of Pt, Ir, Ru, Rh, Re, Os, Pd and their oxides.

10. A semiconductor device according to claim 1, wherein
the lower electrode includes a film of at least one material selected from the group consisting of Pt, Ir, Ru, Rh, Re, Os, Pd and their oxides, and SrRuO₃.

11. A semiconductor device according to claim 7, wherein
the lower electrode includes a film of at least one material selected from the group consisting of Pt, Ir, Ru, Rh, Re, Os, Pd and their oxides, and SrRuO₃.

12. A semiconductor device according to claim 3, wherein
the amorphous noble metal oxide adhesion layer includes a film of at least one material selected from the group consisting of oxides of Pt, Ir, Ru, Rh, Re, Os and Pd, and SrRuO₃.

13. A method of manufacturing a semiconductor device comprising the steps of:
forming a semiconductor element over a semiconductor substrate;
forming an insulation film over the semiconductor substrate with the semiconductor element formed over;
forming a contact hole in the insulation film down to the semiconductor element;
forming a plug buried in the contact hole, connected to the semiconductor element, and including a conduction film of a noble metal or a noble metal oxide; and
forming a capacitor including a lower electrode formed over the insulation film with the plug formed in and connected to the plug, a dielectric film formed over the lower electrode and formed of a ferroelectric film or a high dielectric film, and an upper electrode formed over the dielectric film.

14. A method of manufacturing a semiconductor device according to claim 13, further comprising, after the step of forming the plug and before the step of forming the capacitor, the step of
planarizing the plug including the conduction film.

15. A method of manufacturing a semiconductor device according to claim 14, further comprising, after the step of planarizing the plug and before the step of forming the capacitor, the step of
forming an amorphous noble metal oxide adhesion layer formed over the insulation film with the plug formed in and connected to the plug,
the lower electrode being formed on the amorphous noble metal oxide adhesion layer.

16. A method of manufacturing a semiconductor device according to claim 13, wherein
the plug is formed integral with the lower electrode.

17. A method of manufacturing a semiconductor device according to claim 13, further comprising, after the step of forming the contact hole, the step of
forming an adhesion layer in the contact hole, for ensuring the adhesion of the conduction film to a base.

18. A method of manufacturing a semiconductor device according to claim 13, further comprising the steps of:
forming another insulation film over said insulation film and the capacitor;
forming another contact hole in said another insulation film down to the upper electrode; and
forming over said another insulation film an interconnection connected to the upper electrode via said another contact hole and including a conduction film of a noble metal or a noble metal oxide.

19. A method of manufacturing a semiconductor device according to claim 13, wherein
the conduction film of the plug is formed by MOCVD, LSCVD or CSD.

20. A method of manufacturing a semiconductor device according to claim 13, wherein
the conduction film of the plug includes a film of at least one material selected from the group consisting of Pt, Ir, Ru, Rh, Re, Os, Pd and their oxides.
